(19) United States
(12) Patent Application Publication
(10) Pub. No.: US 2026/0353301 A1
(43) Pub. Date: Nov. 5, 2026

(54) CONSTELLATION LEARNING WITH SUPPORT FOR POWER AMPLIFIER BACKOFF

(71) Applicant: InterDigital Patent Holdings, Inc., Wilmington, DE (US)

(72) Inventors: Daniel Steinbach, Commack, NY (US); Mohamed Amine Arfaoui, Montreal (CA); Asil Koc, Verdun (CA); Philip Pietraski, Jericho, NY (US); Guodong Zhang, Woodbury, NY (US); John Kaewell, Jamison, PA (US)

(73) Assignee: InterDigital Patent Holdings, Inc., Wilmington, DE (US)

(21) Appl. No.: 19/183,617

(22) Filed: Apr. 18, 2025

(51) Int. Cl. H04W 52/14

(52) U.S. Cl. CPC H04W 52/146

(57) ABSTRACT

A wireless transmit/receive unit (WTRU) use learned constellations for uplink transmissions in a wireless communication network. The WTRU may receive configuration information for using learned constellations from a network. The WTRU may receive configuration information for an uplink (UL) transmission, including a modulation and coding scheme (MCS) and/or waveform indicator. The WTRU may determine a power amplitude (PA) backoff level based on the configuration information. The WTRU may determine a constellation pattern to use for the UL transmission (e.g., by indexing a table with the MCS value, waveform indicator, and/or PA backoff level). The WTRU may perform the UL transmission using the constellation pattern. The WTRU may also be capable of training artificial intelligence or machine learning (AIML) models for constellation learning. For example, the WTRU and network may perform end-to-end supervised or reinforcement learning techniques to train AIML models for constellation mapping and soft signal demapping.

### BACKGROUND

Artificial intelligence (AI) may refer to behavior exhibited by machines that mimics cognitive functions to sense, reason, adapt and act. An AI component may refer to the realization of behaviors and/or conformance to requirements by learning based on data, without explicit configuration of sequence of steps of actions. AI components may enable learning complex behaviors which might be difficult to specify and/or implement when using legacy methods.

Machine learning (ML) may refer to algorithms that solve a problem based on learning through experience (e.g., learning using data), without being explicitly programmed (e.g., without being configured with a set of rules). ML can be considered as a subset of AI.

Different ML paradigms may be envisioned based on the nature of data or feedback available to the learning algorithm. In a first example, a supervised learning approach may involve learning a function that maps input to an output based on labeled training examples. Each training example may comprise a pair consisting of an input and its corresponding output. In a second example, an unsupervised learning approach may involve detecting patterns in the data with no pre-existing labels. In a third example, a reinforcement learning approach may involve performing a sequence of actions in an environment to maximize a cumulative reward. In some solutions, it is possible to apply ML algorithms using a combination or interpolation of the above-mentioned approaches. For example, a semi-supervised learning approach may use a combination of a small amount of labeled data with a large amount of unlabeled data during training. In this regard semi-supervised learning falls between unsupervised learning (e.g., with no labeled training data) and supervised learning (e.g., with only labeled training data).

### SUMMARY

Wireless communications systems may include wireless transmit/receive units (WTRUs) and/or network (NW) entities that support constellation learning and/or using learned constellations for communications. The WTRUs and/or NW entities may include hardware components (e.g., processors, memory, etc.) and/or software entities (e.g., programming, applications, features) for constellation learning and/or using learned constellations.

A WTRU may receive configuration information for an uplink (UL) transmission. The configuration information may comprise a modulation and coding scheme (MCS) for the uplink transmission and/or a waveform indicator. The WTRU may determine a power amplifier (PA) backoff level based on the configuration information for the UL transmission. The WTRU may determine a constellation pattern to use for the UL transmission based on the MCS, waveform indicator, and the PA backoff level. The WTRU may perform the UL transmission using the constellation pattern.

The WTRU may send an indication of the PA backoff level to a base station. For example, the WTRU may send an indication of the PA backoff level to a base station whenever the PA backoff level changes from a prior value. For example, the WTRU may send an indication of the PA backoff level to the base station based upon a periodic or aperiodic timer or condition. In some cases, for example, if the PA backoff level is reported periodically, the NW may estimate the PA backoff level. For example, the NW may store the most recent PA backoff level sent and may keep track of any increases or decreases indicated in a transmission power control (TPC) command (e.g., with a step size indicated in the TPC command, in a field), to determine the current PA backoff level.

The WTRU and the NW may engage in signaling related to the WTRU's capabilities for using learned constellations. The WTRU may receive a request to report information related to the WTRU's capabilities for using learned constellations. The WTRU may (e.g., in response to the request) send a message comprising information related to the WTRUS's capabilities for using learned constellations.

The WTRU may receive configuration information for using learned constellations. The configuration information for using learned constellations may comprise an indication that the WTRU is to use learned constellation patterns for one or more UL transmissions.

The WTRU and/or NW, through training, may determine a set and/or table of learned constellations for UL transmissions. The set/table may be indexed by MCS values, waveform indicator, and/or PA backoff level values. A given MCS value, waveform indicator, and/or backoff level may indicate a constellation (e.g., via an index value or identifier).

In examples, the WTRU may receive a request for information about supported PA models and/or PA identification (e.g., a list of PA models supported, a list of PA identification numbers). The WTRU may send a response to the request for information about supported PA models and/or PA identification including the requested information. The WTRU may receive an indication of which PA model to use. The WTRU may (e.g., in the same transmission) receive a request to transmit parameters associated with the indicated PA. The WTRU may receive a set of constellations to be used for inference (e.g., of constellation). The WTRU may receive signaling from the NW comprising new parameters for the PA model at the WTRU.

With respect to training, a WTRU may receive configuration information comprising a set of initial constellations, training bit information (e.g., comprising seed values and/or training bits), training parameters (e.g., learning rates, perturbations, etc.), and/or resource allocations to transmit modulated symbols. The WTRU may create modulated symbols based on the training bit information (e.g., seed values, training bits, etc.) and the set of initial constellations. The WTRU may transmit the modulated symbols to the NW. The WTRU may receive feedback information (e.g., online constellation learning feedback) from the NW. In examples, the feedback information may include gradients of a loss function and/or learned constellation performance metrics (e.g., AIML model loss, bit error rate (BER), block error rate (BLER), throughput information, etc.). The WTRU may train one or more second constellations based on the received feedback information.

### BRIEF DESCRIPTION OF THE DRAWINGS

FIG. 1A is a system diagram illustrating an example communications system in which one or more disclosed embodiments may be implemented.

FIG. 1B is a system diagram illustrating an example wireless transmit/receive unit (WTRU) that may be used within the communications system illustrated in FIG. 1A according to an embodiment.

FIG. 1C is a system diagram illustrating an example radio access network (RAN) and an example core network (CN) that may be used within the communications system illustrated in FIG. 1A according to an embodiment.

FIG. 1D is a system diagram illustrating a further example RAN and a further example CN that may be used within the communications system illustrated in FIG. 1A according to an embodiment.

FIG. 2 is a block diagram showing an example of a Markov decision process (MDP).

FIG. 3 is a flow diagram showing an example visualization of a transmitted/received 16-QAM constellation, with 4 bits per symbol.

FIG. 4 is a flow diagram showing an example visualization of effects caused by noise and distortion on a 16-QAM constellation.

FIG. 5 is a constellation plot showing an example visualization of a learned constellation diagram under non-linear phase noise.

FIG. 6 is a block diagram showing an example of a typical transmit chain in a wireless transmit/receive unit (WTRU).

FIG. 7 is a graph showing an example of relationships between input power and output power for both a linear power amplifier (PA) response and a nonlinear power amplifier response.

FIG. 8 is a system diagram illustrating an example of a system for closed loop power control with transmission power control messaging.

FIG. 9 is a block diagram showing an example of signaling for a learned constellation based upon PA backoff.

FIG. 10 is a constellation plot showing an example of a bit mapping of a learned 64-QAM constellation.

FIG. 11 is a flow chart showing an example of a WTRU procedure for using a learned constellation for physical uplink shared channel (PUSCH) transmission.

FIG. 12 is a block diagram showing an example of signaling for transmitter-side training for constellation learning in uplink communications.

FIG. 13 is a block diagram showing an example of an architecture for an artificial intelligence or machine learning (AIML) based constellation mapper.

FIG. 14 is a block diagram showing an example of an architecture for an AIML based soft symbol demapper.

FIGS. 15A and 15B together are a flow chart showing an example of a WTRU procedure for transmitter-side training for online constellation learning in uplink.

FIG. 16A is a graph showing an example of relationships between signal to noise ratio (SNR) and throughput for 8.5 dB PA power backoff.

FIG. 16B is a graph showing an example of a PA model used during training where the saturation voltage Vsat=1.5V.

FIG. 17A and FIG. 17B are constellation plots showing examples of learned constellations for six bits per symbol, with PA power backoff set to 8.5 decibels (dB) and 3.5 dB.

### DETAILED DESCRIPTION

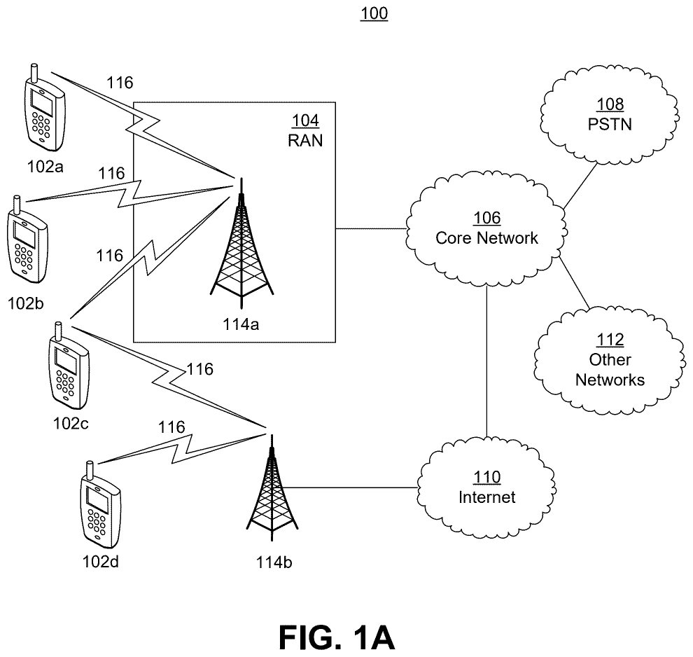

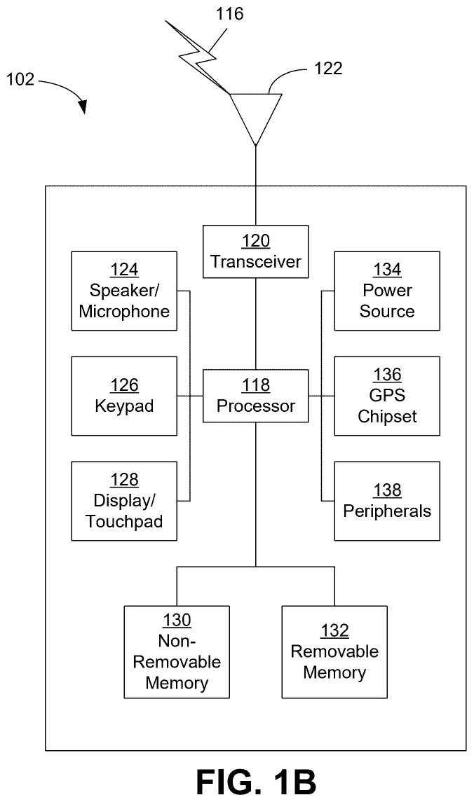

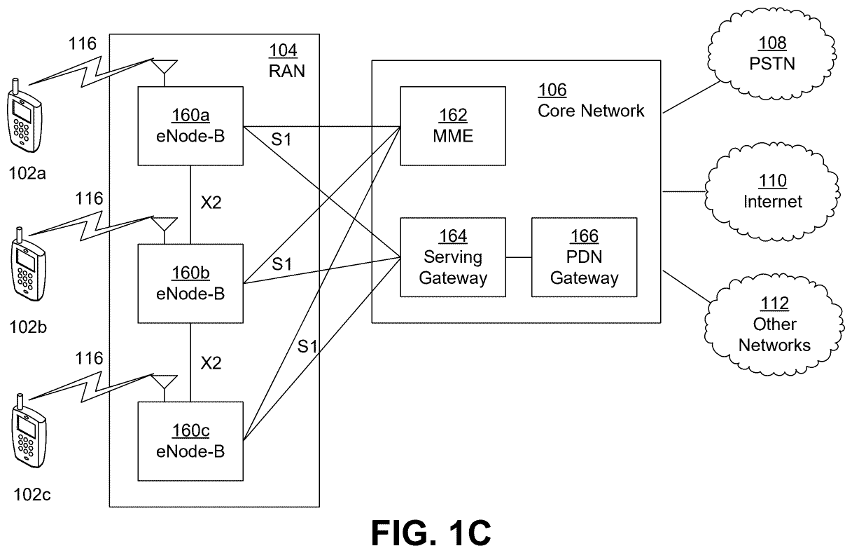

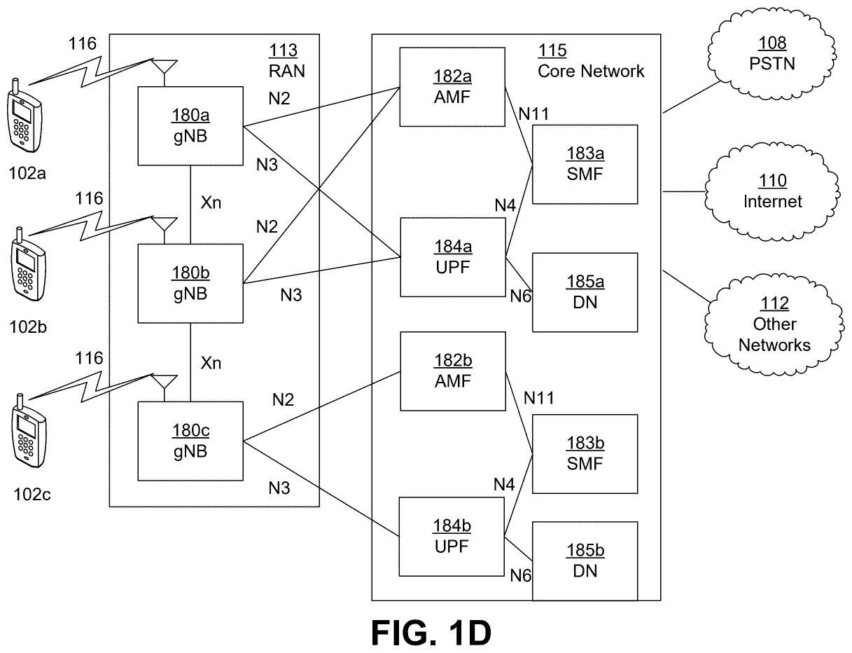

FIG. 1A is a diagram illustrating an example communications system 100 in which one or more disclosed embodiments may be implemented. The communications system 100 may be a multiple access system that provides content, such as voice, data, video, messaging, broadcast, etc., to multiple wireless users. The communications system 100 may enable multiple wireless users to access such content through the sharing of system resources, including wireless bandwidth. For example, the communications systems 100 may employ one or more channel access methods, such as code division multiple access (CDMA), time division multiple access (TDMA), frequency division multiple access (FDMA), orthogonal FDMA (OFDMA), single-carrier FDMA (SC-FDMA), zero-tail unique-word DFT-Spread OFDM (ZT UW DTS-s OFDM), unique word OFDM (UW-OFDM), resource block-filtered OFDM, filter bank multicarrier (FBMC), and the like.

As shown in FIG. 1A, the communications system 100 may include wireless transmit/receive units (WTRUs) 102a, 102b, 102c, 102d, a RAN 104/113, a CN 106/115, a public switched telephone network (PSTN) 108, the Internet 110, and other networks 112, though it will be appreciated that the disclosed embodiments contemplate any number of WTRUs, base stations, networks, and/or network elements. Each of the WTRUs 102a, 102b, 102c, 102d may be any type of device configured to operate and/or communicate in a wireless environment. By way of example, the WTRUs 102a, 102b, 102c, 102d, any of which may be referred to as a “station” and/or a “STA”, may be configured to transmit and/or receive wireless signals and may include a user equipment (WTRU), a mobile station, a fixed or mobile subscriber unit, a subscription-based unit, a pager, a cellular telephone, a personal digital assistant (PDA), a smartphone, a laptop, a netbook, a personal computer, a wireless sensor, a hotspot or Wi-Fi device, an Internet of Things (IoT) device, a watch or other wearable, a head-mounted display (HMD), a vehicle, a drone, a medical device and applications (e.g., remote surgery), an industrial device and applications (e.g., a robot and/or other wireless devices operating in an industrial and/or an automated processing chain contexts), a consumer electronics device, a device operating on commercial and/or industrial wireless networks, and the like. Any of the WTRUs 102a, 102b, 102c and 102d may be interchangeably referred to as a WTRU. Further, any description herein that is described with reference to a UE may be equally applicable to a WTRU (or vice versa). For example, a WTRU may be configured to perform any of the processes or procedures described herein as being performed by a UE (or vice versa).

The communications systems 100 may also include a base station 114a and/or a base station 114b. Each of the base stations 114a, 114b may be any type of device configured to wirelessly interface with at least one of the WTRUs 102a, 102b, 102c, 102d to facilitate access to one or more communication networks, such as the CN 106/115, the Internet 110, and/or the other networks 112. By way of example, the base stations 114a, 114b may be a base transceiver station (BTS), a Node-B, an eNode B, a Home Node B, a Home eNode B, a gNB, a NR NodeB, a site controller, an access point (AP), a wireless router, and the like. While the base stations 114a, 114b are each depicted as a single element, it will be appreciated that the base stations 114a, 114b may include any number of interconnected base stations and/or network elements.

The base station 114a may be part of the RAN 104/113, which may also include other base stations and/or network elements (not shown), such as a base station controller (BSC), a radio network controller (RNC), relay nodes, etc. The base station 114a and/or the base station 114b may be configured to transmit and/or receive wireless signals on one or more carrier frequencies, which may be referred to as a cell (not shown). These frequencies may be in licensed spectrum, unlicensed spectrum, or a combination of licensed and unlicensed spectrum. A cell may provide coverage for a wireless service to a specific geographical area that may be relatively fixed or that may change over time. The cell may further be divided into cell sectors. For example, the cell associated with the base station 114a may be divided into three sectors. Thus, in one embodiment, the base station 114a may include three transceivers, i.e., one for each sector of the cell. In an embodiment, the base station 114a may employ multiple-input multiple output (MIMO) technology and may utilize multiple transceivers for each sector of the cell. For example, beamforming may be used to transmit and/or receive signals in desired spatial directions.

The base stations 114a, 114b may communicate with one or more of the WTRUs 102a, 102b, 102c, 102d over an air interface 116, which may be any suitable wireless communication link (e.g., radio frequency (RF), microwave, centimeter wave, micrometer wave, infrared (IR), ultraviolet (UV), visible light, etc.). The air interface 116 may be established using any suitable radio access technology (RAT).

More specifically, as noted above, the communications system 100 may be a multiple access system and may employ one or more channel access schemes, such as CDMA, TDMA, FDMA, OFDMA, SC-FDMA, and the like. For example, the base station 114a in the RAN 104/113 and the WTRUs 102a, 102b, 102c may implement a radio technology such as Universal Mobile Telecommunications System (UMTS) Terrestrial Radio Access (UTRA), which may establish the air interface 115/116/117 using wideband CDMA (WCDMA). WCDMA may include communication protocols such as High-Speed Packet Access (HSPA) and/or Evolved HSPA (HSPA+). HSPA may include High-Speed Downlink (DL) Packet Access (HSDPA) and/or High-Speed UL Packet Access (HSUPA).

In an embodiment, the base station 114a and the WTRUs 102a, 102b, 102c may implement a radio technology such as Evolved UMTS Terrestrial Radio Access (E-UTRA), which may establish the air interface 116 using Long Term Evolution (LTE) and/or LTE-Advanced (LTE-A) and/or LTE-Advanced Pro (LTE-A Pro).

In an embodiment, the base station 114a and the WTRUs 102a, 102b, 102c may implement a radio technology such as NR Radio Access, which may establish the air interface 116 using New Radio (NR).

In an embodiment, the base station 114a and the WTRUs 102a, 102b, 102c may implement multiple radio access technologies. For example, the base station 114a and the WTRUs 102a, 102b, 102c may implement LTE radio access and NR radio access together, for instance using dual connectivity (DC) principles. Thus, the air interface utilized by WTRUs 102a, 102b, 102c may be characterized by multiple types of radio access technologies and/or transmissions sent to/from multiple types of base stations (e.g., an eNB and a gNB).

In other embodiments, the base station 114a and the WTRUs 102a, 102b, 102c may implement radio technologies such as IEEE 802.11 (i.e., Wireless Fidelity (WiFi), IEEE 802.16 (i.e., Worldwide Interoperability for Microwave Access (WiMAX)), CDMA2000, CDMA2000 1×, CDMA2000 EV-DO, Interim Standard 2000 (IS-2000), Interim Standard 95 (IS-95), Interim Standard 856 (IS-856), Global System for Mobile communications (GSM), Enhanced Data rates for GSM Evolution (EDGE), GSM EDGE (GERAN), and the like.

The base station 114b in FIG. 1A may be a wireless router, Home Node B, Home eNode B, or access point, for example, and may utilize any suitable RAT for facilitating wireless connectivity in a localized area, such as a place of business, a home, a vehicle, a campus, an industrial facility, an air corridor (e.g., for use by drones), a roadway, and the like. In one embodiment, the base station 114b and the WTRUs 102c, 102d may implement a radio technology such as IEEE 802.11 to establish a wireless local area network (WLAN). In an embodiment, the base station 114b and the WTRUs 102c, 102d may implement a radio technology such as IEEE 802.15 to establish a wireless personal area network (WPAN). In yet another embodiment, the base station 114b and the WTRUs 102c, 102d may utilize a cellular-based RAT (e.g., WCDMA, CDMA2000, GSM, LTE, LTE-A, LTE-A Pro, NR etc.) to establish a picocell or femtocell. As shown in FIG. 1A, the base station 114b may have a direct connection to the Internet 110. Thus, the base station 114b may not be required to access the Internet 110 via the CN 106/115.

The RAN 104/113 may be in communication with the CN 106/115, which may be any type of network configured to provide voice, data, applications, and/or voice over internet protocol (VoIP) services to one or more of the WTRUs 102a, 102b, 102c, 102d. The data may have varying quality of service (QoS) requirements, such as differing throughput requirements, latency requirements, error tolerance requirements, reliability requirements, data throughput requirements, mobility requirements, and the like. The CN 106/115 may provide call control, billing services, mobile location-based services, pre-paid calling, Internet connectivity, video distribution, etc., and/or perform high-level security functions, such as user authentication. Although not shown in FIG. 1A, it will be appreciated that the RAN 104/113 and/or the CN 106/115 may be in direct or indirect communication with other RANs that employ the same RAT as the RAN 104/113 or a different RAT. For example, in addition to being connected to the RAN 104/113, which may be utilizing a NR radio technology, the CN 106/115 may also be in communication with another RAN (not shown) employing a GSM, UMTS, CDMA 2000, WiMAX, E-UTRA, or WiFi radio technology.

The CN 106/115 may also serve as a gateway for the WTRUs 102a, 102b, 102c, 102d to access the PSTN 108, the Internet 110, and/or the other networks 112. The PSTN 108 may include circuit-switched telephone networks that provide plain old telephone service (POTS). The Internet 110 may include a global system of interconnected computer networks and devices that use common communication protocols, such as the transmission control protocol (TCP), user datagram protocol (UDP) and/or the internet protocol (IP) in the TCP/IP internet protocol suite. The networks 112 may include wired and/or wireless communications networks owned and/or operated by other service providers. For example, the networks 112 may include another CN connected to one or more RANs, which may employ the same RAT as the RAN 104/113 or a different RAT.

Some or all of the WTRUs 102a, 102b, 102c, 102d in the communications system 100 may include multi-mode capabilities (e.g., the WTRUs 102a, 102b, 102c, 102d may include multiple transceivers for communicating with different wireless networks over different wireless links). For example, the WTRU 102c shown in FIG. 1A may be configured to communicate with the base station 114a, which may employ a cellular-based radio technology, and with the base station 114b, which may employ an IEEE 802 radio technology.

FIG. 1B is a system diagram illustrating an example WTRU 102. As shown in FIG. 1B, the WTRU 102 may include a processor 118, a transceiver 120, a transmit/receive element 122, a speaker/microphone 124, a keypad 126, a display/touchpad 128, non-removable memory 130, removable memory 132, a power source 134, a global positioning system (GPS) chipset 136, and/or other peripherals 138, among others. It will be appreciated that the WTRU 102 may include any sub-combination of the foregoing elements while remaining consistent with an embodiment.

The processor 118 may be a general purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), a state machine, and the like. The processor 118 may perform signal coding, data processing, power control, input/output processing, and/or any other functionality that enables the WTRU 102 to operate in a wireless environment. The processor 118 may be coupled to the transceiver 120, which may be coupled to the transmit/receive element 122. While FIG. 1B depicts the processor 118 and the transceiver 120 as separate components, it will be appreciated that the processor 118 and the transceiver 120 may be integrated together in an electronic package or chip.

The transmit/receive element 122 may be configured to transmit signals to, or receive signals from, a base station (e.g., the base station 114a) over the air interface 116. For example, in one embodiment, the transmit/receive element 122 may be an antenna configured to transmit and/or receive RF signals. In an embodiment, the transmit/receive element 122 may be an emitter/detector configured to transmit and/or receive IR, UV, or visible light signals, for example. In yet another embodiment, the transmit/receive element 122 may be configured to transmit and/or receive both RF and light signals. It will be appreciated that the transmit/receive element 122 may be configured to transmit and/or receive any combination of wireless signals.

Although the transmit/receive element 122 is depicted in FIG. 1B as a single element, the WTRU 102 may include any number of transmit/receive elements 122. More specifically, the WTRU 102 may employ MIMO technology. Thus, in one embodiment, the WTRU 102 may include two or more transmit/receive elements 122 (e.g., multiple antennas) for transmitting and receiving wireless signals over the air interface 116.

The transceiver 120 may be configured to modulate the signals that are to be transmitted by the transmit/receive element 122 and to demodulate the signals that are received by the transmit/receive element 122. As noted above, the WTRU 102 may have multi-mode capabilities. Thus, the transceiver 120 may include multiple transceivers for enabling the WTRU 102 to communicate via multiple RATs, such as NR and IEEE 802.11, for example.

The processor 118 of the WTRU 102 may be coupled to, and may receive user input data from, the speaker/microphone 124, the keypad 126, and/or the display/touchpad 128 (e.g., a liquid crystal display (LCD) display unit or organic light-emitting diode (OLED) display unit). The processor 118 may also output user data to the speaker/microphone 124, the keypad 126, and/or the display/touchpad 128. In addition, the processor 118 may access information from, and store data in, any type of suitable memory, such as the non-removable memory 130 and/or the removable memory 132. The non-removable memory 130 may include random-access memory (RAM), read-only memory (ROM), a hard disk, or any other type of memory storage device. The removable memory 132 may include a subscriber identity module (SIM) card, a memory stick, a secure digital (SD) memory card, and the like. In other embodiments, the processor 118 may access information from, and store data in, memory that is not physically located on the WTRU 102, such as on a server or a home computer (not shown).

The processor 118 may receive power from the power source 134, and may be configured to distribute and/or control the power to the other components in the WTRU 102. The power source 134 may be any suitable device for powering the WTRU 102. For example, the power source 134 may include one or more dry cell batteries (e.g., nickel-cadmium (NiCd), nickel-zinc (NiZn), nickel metal hydride (NiMH), lithium-ion (Li-ion), etc.), solar cells, fuel cells, and the like.

The processor 118 may also be coupled to the GPS chipset 136, which may be configured to provide location information (e.g., longitude and latitude) regarding the current location of the WTRU 102. In addition to, or in lieu of, the information from the GPS chipset 136, the WTRU 102 may receive location information over the air interface 116 from a base station (e.g., base stations 114a, 114b) and/or determine its location based on the timing of the signals being received from two or more nearby base stations. It will be appreciated that the WTRU 102 may acquire location information by way of any suitable location-determination method while remaining consistent with an embodiment.

The processor 118 may further be coupled to other peripherals 138, which may include one or more software and/or hardware modules that provide additional features, functionality and/or wired or wireless connectivity. For example, the peripherals 138 may include an accelerometer, an e-compass, a satellite transceiver, a digital camera (for photographs and/or video), a universal serial bus (USB) port, a vibration device, a television transceiver, a hands free headset, a Bluetooth® module, a frequency modulated (FM) radio unit, a digital music player, a media player, a video game player module, an Internet browser, a Virtual Reality and/or Augmented Reality (VR/AR) device, an activity tracker, and the like. The peripherals 138 may include one or more sensors, the sensors may be one or more of a gyroscope, an accelerometer, a hall effect sensor, a magnetometer, an orientation sensor, a proximity sensor, a temperature sensor, a time sensor; a geolocation sensor; an altimeter, a light sensor, a touch sensor, a magnetometer, a barometer, a gesture sensor, a biometric sensor, and/or a humidity sensor.

The WTRU 102 may include a full duplex radio for which transmission and reception of some or all of the signals (e.g., associated with particular subframes for both the UL (e.g., for transmission) and downlink (e.g., for reception) may be concurrent and/or simultaneous. The full duplex radio may include an interference management unit 139 to reduce and or substantially eliminate self-interference via either hardware (e.g., a choke) or signal processing via a processor (e.g., a separate processor (not shown) or via processor 118). In an embodiment, the WRTU 102 may include a half-duplex radio for which transmission and reception of some or all of the signals (e.g., associated with particular subframes for either the UL (e.g., for transmission) or the downlink (e.g., for reception)).

FIG. 1C is a system diagram illustrating the RAN 104 and the CN 106 according to an embodiment. As noted above, the RAN 104 may employ an E-UTRA radio technology to communicate with the WTRUs 102a, 102b, 102c over the air interface 116. The RAN 104 may also be in communication with the CN 106.

The RAN 104 may include eNode-Bs 160a, 160b, 160c, though it will be appreciated that the RAN 104 may include any number of eNode-Bs while remaining consistent with an embodiment. The eNode-Bs 160a, 160b, 160c may each include one or more transceivers for communicating with the WTRUs 102a, 102b, 102c over the air interface 116. In one embodiment, the eNode-Bs 160a, 160b, 160c may implement MIMO technology. Thus, the eNode-B 160a, for example, may use multiple antennas to transmit wireless signals to, and/or receive wireless signals from, the WTRU 102a.

Each of the eNode-Bs 160a, 160b, 160c may be associated with a particular cell (not shown) and may be configured to handle radio resource management decisions, handover decisions, scheduling of users in the UL and/or DL, and the like. As shown in FIG. 1C, the eNode-Bs 160a, 160b, 160c may communicate with one another over an X2 interface.

The CN 106 shown in FIG. 1C may include a mobility management entity (MME) 162, a serving gateway (SGW) 164, and a packet data network (PDN) gateway (or PGW) 166. While each of the foregoing elements are depicted as part of the CN 106, it will be appreciated that any of these elements may be owned and/or operated by an entity other than the CN operator.

The MME 162 may be connected to each of the eNode-Bs 162a, 162b, 162c in the RAN 104 via an S1 interface and may serve as a control node. For example, the MME 162 may be responsible for authenticating users of the WTRUs 102a, 102b, 102c, bearer activation/deactivation, selecting a particular serving gateway during an initial attach of the WTRUs 102a, 102b, 102c, and the like. The MME 162 may provide a control plane function for switching between the RAN 104 and other RANs (not shown) that employ other radio technologies, such as GSM and/or WCDMA.

The SGW 164 may be connected to each of the eNode Bs 160a, 160b, 160c in the RAN 104 via the S1 interface. The SGW 164 may generally route and forward user data packets to/from the WTRUs 102a, 102b, 102c. The SGW 164 may perform other functions, such as anchoring user planes during inter-eNode B handovers, triggering paging when DL data is available for the WTRUs 102a, 102b, 102c, managing and storing contexts of the WTRUs 102a, 102b, 102c, and the like.

The SGW 164 may be connected to the PGW 166, which may provide the WTRUs 102a, 102b, 102c with access to packet-switched networks, such as the Internet 110, to facilitate communications between the WTRUs 102a, 102b, 102c and IP-enabled devices.

The CN 106 may facilitate communications with other networks. For example, the CN 106 may provide the WTRUs 102a, 102b, 102c with access to circuit-switched networks, such as the PSTN 108, to facilitate communications between the WTRUs 102a, 102b, 102c and traditional land-line communications devices. For example, the CN 106 may include, or may communicate with, an IP gateway (e.g., an IP multimedia subsystem (IMS) server) that serves as an interface between the CN 106 and the PSTN 108. In addition, the CN 106 may provide the WTRUs 102a, 102b, 102c with access to the other networks 112, which may include other wired and/or wireless networks that are owned and/or operated by other service providers.

Although the WTRU is described in FIGS. 1A-1D as a wireless terminal, it is contemplated that in certain representative embodiments that such a terminal may use (e.g., temporarily, or permanently) wired communication interfaces with the communication network.

In representative embodiments, the other network 112 may be a WLAN.

A WLAN in Infrastructure Basic Service Set (BSS) mode may have an Access Point (AP) for the BSS and one or more stations (STAs) associated with the AP. The AP may have an access or an interface to a Distribution System (DS) or another type of wired/wireless network that carries traffic in to and/or out of the BSS. Traffic to STAs that originates from outside the BSS may arrive through the AP and may be delivered to the STAs. Traffic originating from STAs to destinations outside the BSS may be sent to the AP to be delivered to respective destinations. Traffic between STAs within the BSS may be sent through the AP, for example, where the source STA may send traffic to the AP and the AP may deliver the traffic to the destination STA. The traffic between STAs within a BSS may be considered and/or referred to as peer-to-peer traffic. The peer-to-peer traffic may be sent between (e.g., directly between) the source and destination STAs with a direct link setup (DLS). In certain representative embodiments, the DLS may use an 802.11e DLS or an 802.11z tunneled DLS (TDLS). A WLAN using an Independent BSS (IBSS) mode may not have an AP, and the STAs (e.g., all of the STAs) within or using the IBSS may communicate directly with each other. The IBSS mode of communication may sometimes be referred to herein as an “ad-hoc” mode of communication.

When using the 802.11ac infrastructure mode of operation or a similar mode of operations, the AP may transmit a beacon on a fixed channel, such as a primary channel. The primary channel may be a fixed width (e.g., 20 MHz wide bandwidth) or a dynamically set width via signaling. The primary channel may be the operating channel of the BSS and may be used by the STAs to establish a connection with the AP. In certain representative embodiments, Carrier Sense Multiple Access with Collision Avoidance (CSMA/CA) may be implemented, for example in in 802.11 systems. For CSMA/CA, the STAs (e.g., every STA), including the AP, may sense the primary channel. If the primary channel is sensed/detected and/or determined to be busy by a particular STA, the particular STA may back off. One STA (e.g., only one station) may transmit at any given time in a given BSS.

High Throughput (HT) STAs may use a 40 MHz wide channel for communication, for example, via a combination of the primary 20 MHz channel with an adjacent or nonadjacent 20 MHz channel to form a 40 MHz wide channel.

Very High Throughput (VHT) STAs may support 20 MHz, 40 MHz, 80 MHz, and/or 160 MHz wide channels. The 40 MHz, and/or 80 MHz, channels may be formed by combining contiguous 20 MHz channels. A 160 MHz channel may be formed by combining 8 contiguous 20 MHz channels, or by combining two non-contiguous 80 MHz channels, which may be referred to as an 80+80 configuration. For the 80+80 configuration, the data, after channel encoding, may be passed through a segment parser that may divide the data into two streams. Inverse Fast Fourier Transform (IFFT) processing, and time domain processing, may be done on each stream separately. The streams may be mapped on to the two 80 MHz channels, and the data may be transmitted by a transmitting STA. At the receiver of the receiving STA, the above described operation for the 80+80 configuration may be reversed, and the combined data may be sent to the Medium Access Control (MAC).

Sub 1 GHz modes of operation are supported by 802.11af and 802.11ah. The channel operating bandwidths, and carriers, are reduced in 802.11af and 802.11ah relative to those used in 802.11n, and 802.11ac. 802.11af supports 5 MHz, 10 MHz and 20 MHz bandwidths in the TV White Space (TVWS) spectrum, and 802.11ah supports 1 MHz, 2 MHz, 4 MHz, 8 MHz, and 16 MHz bandwidths using non-TVWS spectrum. According to a representative embodiment, 802.11ah may support Meter Type Control/Machine-Type Communications, such as MTC devices in a macro coverage area. MTC devices may have certain capabilities, for example, limited capabilities including support for (e.g., only support for) certain and/or limited bandwidths. The MTC devices may include a battery with a battery life above a threshold (e.g., to maintain a very long battery life).

WLAN systems, which may support multiple channels, and channel bandwidths, such as 802.11n, 802.11ac, 802.11af, and 802.11ah, include a channel which may be designated as the primary channel. The primary channel may have a bandwidth equal to the largest common operating bandwidth supported by all STAs in the BSS. The bandwidth of the primary channel may be set and/or limited by a STA, from among all STAs in operating in a BSS, which supports the smallest bandwidth operating mode. In the example of 802.11ah, the primary channel may be 1 MHz wide for STAs (e.g., MTC type devices) that support (e.g., only support) a 1 MHz mode, even if the AP, and other STAs in the BSS support 2 MHz, 4 MHz, 8 MHz, 16 MHz, and/or other channel bandwidth operating modes. Carrier sensing and/or Network Allocation Vector (NAV) settings may depend on the status of the primary channel. If the primary channel is busy, for example, due to a STA (which supports only a 1 MHz operating mode), transmitting to the AP, the entire available frequency bands may be considered busy even though a majority of the frequency bands remains idle and may be available.

In the United States, the available frequency bands, which may be used by 802.11ah, are from 902 MHz to 928 MHz. In Korea, the available frequency bands are from 917.5 MHz to 923.5 MHz. In Japan, the available frequency bands are from 916.5 MHz to 927.5 MHz. The total bandwidth available for 802.11ah is 6 MHz to 26 MHz depending on the country code.

FIG. 1D is a system diagram illustrating the RAN 113 and the CN 115 according to an embodiment. As noted above, the RAN 113 may employ an NR radio technology to communicate with the WTRUs 102a, 102b, 102c over the air interface 116. The RAN 113 may also be in communication with the CN 115.

The RAN 113 may include gNBs 180a, 180b, 180c, though it will be appreciated that the RAN 113 may include any number of gNBs while remaining consistent with an embodiment. The gNBs 180a, 180b, 180c may each include one or more transceivers for communicating with the WTRUs 102a, 102b, 102c over the air interface 116. In one embodiment, the gNBs 180a, 180b, 180c may implement MIMO technology. For example, gNBs 180a, 108b may utilize beamforming to transmit signals to and/or receive signals from the gNBs 180a, 180b, 180c. Thus, the gNB 180a, for example, may use multiple antennas to transmit wireless signals to, and/or receive wireless signals from, the WTRU 102a. In an embodiment, the gNBs 180a, 180b, 180c may implement carrier aggregation technology. For example, the gNB 180a may transmit multiple component carriers to the WTRU 102a (not shown). A subset of these component carriers may be on unlicensed spectrum while the remaining component carriers may be on licensed spectrum. In an embodiment, the gNBs 180a, 180b, 180c may implement Coordinated Multi-Point (COMP) technology. For example, WTRU 102a may receive coordinated transmissions from gNB 180a and gNB 180b (and/or gNB 180c).

The WTRUs 102a, 102b, 102c may communicate with gNBs 180a, 180b, 180c using transmissions associated with a scalable numerology. For example, the OFDM symbol spacing and/or OFDM subcarrier spacing may vary for different transmissions, different cells, and/or different portions of the wireless transmission spectrum. The WTRUs 102a, 102b, 102c may communicate with gNBs 180a, 180b, 180c using subframe or transmission time intervals (TTIs) of various or scalable lengths (e.g., containing varying number of OFDM symbols and/or lasting varying lengths of absolute time).

The gNBs 180a, 180b, 180c may be configured to communicate with the WTRUs 102a, 102b, 102c in a standalone configuration and/or a non-standalone configuration. In the standalone configuration, WTRUs 102a, 102b, 102c may communicate with gNBs 180a, 180b, 180c without also accessing other RANs (e.g., such as eNode-Bs 160a, 160b, 160c). In the standalone configuration, WTRUs 102a, 102b, 102c may utilize one or more of gNBs 180a, 180b, 180c as a mobility anchor point. In the standalone configuration, WTRUs 102a, 102b, 102c may communicate with gNBs 180a, 180b, 180c using signals in an unlicensed band. In a non-standalone configuration WTRUs 102a, 102b, 102c may communicate with/connect to gNBs 180a, 180b, 180c while also communicating with/connecting to another RAN such as eNode-Bs 160a, 160b, 160c. For example, WTRUs 102a, 102b, 102c may implement DC principles to communicate with one or more gNBs 180a, 180b, 180c and one or more eNode-Bs 160a, 160b, 160c substantially simultaneously. In the non-standalone configuration, eNode-Bs 160a, 160b, 160c may serve as a mobility anchor for WTRUs 102a, 102b, 102c and gNBs 180a, 180b, 180c may provide additional coverage and/or throughput for servicing WTRUs 102a, 102b, 102c.

Each of the gNBs 180a, 180b, 180c may be associated with a particular cell (not shown) and may be configured to handle radio resource management decisions, handover decisions, scheduling of users in the UL and/or DL, support of network slicing, dual connectivity, interworking between NR and E-UTRA, routing of user plane data towards User Plane Function (UPF) 184a, 184b, routing of control plane information towards Access and Mobility Management Function (AMF) 182a, 182b and the like. As shown in FIG. 1D, the gNBs 180a, 180b, 180c may communicate with one another over an Xn interface.

The CN 115 shown in FIG. 1D may include at least one AMF 182a, 182b, at least one UPF 184a, 184b, at least one Session Management Function (SMF) 183a, 183b, and possibly a Data Network (DN) 185a, 185b. While each of the foregoing elements are depicted as part of the CN 115, it will be appreciated that any of these elements may be owned and/or operated by an entity other than the CN operator.

The AMF 182a, 182b may be connected to one or more of the gNBs 180a, 180b, 180c in the RAN 113 via an N2 interface and may serve as a control node. For example, the AMF 182a, 182b may be responsible for authenticating users of the WTRUs 102a, 102b, 102c, support for network slicing (e.g., handling of different PDU sessions with different requirements), selecting a particular SMF 183a, 183b, management of the registration area, termination of NAS signaling, mobility management, and the like. Network slicing may be used by the AMF 182a, 182b in order to customize CN support for WTRUs 102a, 102b, 102c based on the types of services being utilized WTRUs 102a, 102b, 102c. For example, different network slices may be established for different use cases such as services relying on ultra-reliable low latency (URLLC) access, services relying on enhanced massive mobile broadband (eMBB) access, services for machine type communication (MTC) access, and/or the like. The AMF 162 may provide a control plane function for switching between the RAN 113 and other RANs (not shown) that employ other radio technologies, such as LTE, LTE-A, LTE-A Pro, and/or non-3GPP access technologies such as WiFi.

The SMF 183a, 183b may be connected to an AMF 182a, 182b in the CN 115 via an N11 interface. The SMF 183a, 183b may also be connected to a UPF 184a, 184b in the CN 115 via an N4 interface. The SMF 183a, 183b may select and control the UPF 184a, 184b and configure the routing of traffic through the UPF 184a, 184b. The SMF 183a, 183b may perform other functions, such as managing and allocating WTRU IP address, managing PDU sessions, controlling policy enforcement and QoS, providing downlink data notifications, and the like. A PDU session type may be IP-based, non-IP based, Ethernet-based, and the like.

The UPF 184a, 184b may be connected to one or more of the gNBs 180a, 180b, 180c in the RAN 113 via an N3 interface, which may provide the WTRUs 102a, 102b, 102c with access to packet-switched networks, such as the Internet 110, to facilitate communications between the WTRUs 102a, 102b, 102c and IP-enabled devices. The UPF 184, 184b may perform other functions, such as routing and forwarding packets, enforcing user plane policies, supporting multi-homed PDU sessions, handling user plane QoS, buffering downlink packets, providing mobility anchoring, and the like.

The CN 115 may facilitate communications with other networks. For example, the CN 115 may include, or may communicate with, an IP gateway (e.g., an IP multimedia subsystem (IMS) server) that serves as an interface between the CN 115 and the PSTN 108. In addition, the CN 115 may provide the WTRUs 102a, 102b, 102c with access to the other networks 112, which may include other wired and/or wireless networks that are owned and/or operated by other service providers. In one embodiment, the WTRUs 102a, 102b, 102c may be connected to a local Data Network (DN) 185a, 185b through the UPF 184a, 184b via the N3 interface to the UPF 184a, 184b and an N6 interface between the UPF 184a, 184b and the DN 185a, 185b.

In view of FIGS. 1A-1D, and the corresponding description of FIGS. 1A-1D, one or more, or all, of the functions described herein with regard to one or more of: WTRU 102a-d, Base Station 114a-b, eNode-B 160a-c, MME 162, SGW 164, PGW 166, gNB 180a-c, AMF 182a-ab, UPF 184a-b, SMF 183a-b, DN 185a-b, and/or any other device(s) described herein, may be performed by one or more emulation devices (not shown). The emulation devices may be one or more devices configured to emulate one or more, or all, of the functions described herein. For example, the emulation devices may be used to test other devices and/or to simulate network and/or WTRU functions.

The emulation devices may be designed to implement one or more tests of other devices in a lab environment and/or in an operator network environment. For example, the one or more emulation devices may perform the one or more, or all, functions while being fully or partially implemented and/or deployed as part of a wired and/or wireless communication network in order to test other devices within the communication network. The one or more emulation devices may perform the one or more, or all, functions while being temporarily implemented/deployed as part of a wired and/or wireless communication network. The emulation device may be directly coupled to another device for purposes of testing and/or may performing testing using over-the-air wireless communications.

The one or more emulation devices may perform the one or more, including all, functions while not being implemented/deployed as part of a wired and/or wireless communication network. For example, the emulation devices may be utilized in a testing scenario in a testing laboratory and/or a non-deployed (e.g., testing) wired and/or wireless communication network in order to implement testing of one or more components. The one or more emulation devices may be test equipment. Direct RF coupling and/or wireless communications via RF circuitry (e.g., which may include one or more antennas) may be used by the emulation devices to transmit and/or receive data.

Communications systems including 5G and similar systems may use power amplifiers (PA) that exhibit nonlinear gain and/or phase. Using receiver-side training for online constellation learning through reinforcement learning and/or through off-line supervised learning may increase the systems' performance.

Deep learning refers to a class of ML algorithms that employ artificial neural networks, for example, Deep Neural Networks (DNNs), which were loosely inspired by biological systems. The DNNs are a special class of ML models that are inspired by the human brain wherein the input is linearly transformed and passes through one or more non-linear activation function(s) multiple times. DNNs typically comprise multiple layers where each layer comprises a linear transformation and/or a given non-linear activation function. The DNNs can be trained using the training data via back-propagation algorithm. Recently, DNNs have shown state-of-the-art performance in a variety of domains (e.g., speech, vision, natural language, wireless communication, etc.), and for various ML settings (e.g., supervised, un-supervised, semi-supervised, etc.).

Reinforcement learning (RL) is a branch of ML that focuses on decision-making by autonomous agents. An autonomous agent may refer to a system or apparatus capable of making independent decisions and responding to its surroundings without direct human intervention. By contrast to supervised and supervised learning, RL agents learn to act and to execute tasks through trial and error, without explicit human guidance. This approach specifically tackles sequential decision-making challenges within dynamic environments.

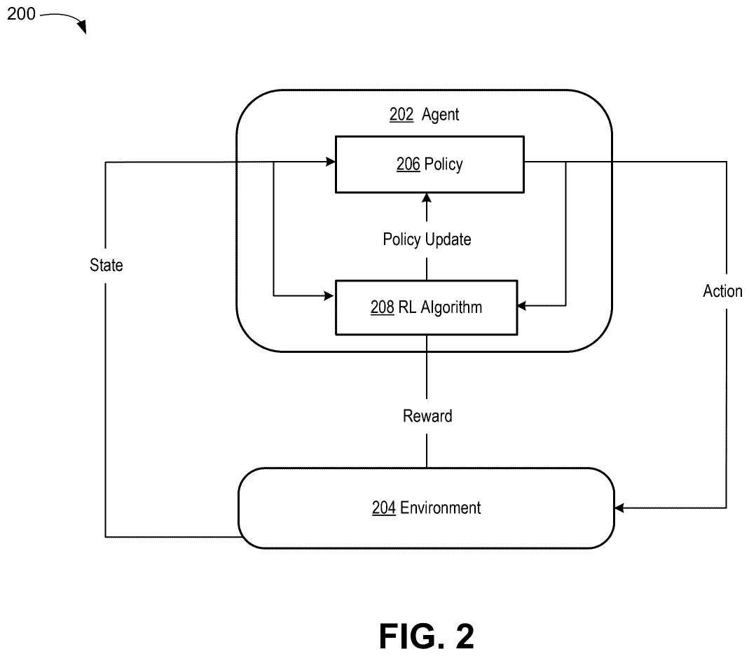

Reinforcement learning may involve one or more relationships between an agent, an environment, and a goal. As depicted in FIG. 2, this relationship is formulated in terms of the Markov decision process (MDP). FIG. 2 is a block diagram showing an example visualization of an MDP. The reinforcement learning agent 202 learns about a problem by interacting with its environment 204. The environment 204 provides information on its current state. The agent 202 then uses that information to determine which actions to take. The decided action moves the environment 204 from its current state to a new state. If that action obtains a positive reward signal from the surrounding environment, the agent 204 is encouraged to take that action again when in a similar state. This process repeats for every new state thereafter. Over time, the agent learns from rewards and penalties to take actions within the environment that meet a specified goal. In MDP, state space refers to some or all of the information provided by an environment's state and action space refers to some or all of the possible actions the agent may take within a state.

An agent may comprise one or more components. In the example shown in FIG. 2, the agent 202 comprises two components: a policy 206 and a learning algorithm 208. The policy 206 comprises a mapping from the current state to a probability distribution of the actions to be taken. Within an agent 202, the policy 206 is implemented by a function approximator with tunable parameters and one or more specific approximation models, such as neural networks. The learning algorithm 208 continuously or continually updates the policy parameters based on the actions, states, and rewards. The goal of the learning algorithm 208 may be to find an optimal policy that maximizes the expected cumulative long-term reward.

An RL agent may have no manually labeled input data guiding its behavior. Thus, it may explore its environment, attempting new actions to discover those that receive rewards. From these reward signals, the agent learns to prefer actions for which it was rewarded in order to maximize its gain. But the agent may continue exploring new states and actions as well. By doing so, it can then use that experience to improve its decision-making. RL algorithms thus may require an agent to both exploit knowledge of previously rewarded state-actions and explore other state-actions. The agent may be configured to avoid exclusively pursuing exploration or exploitation. It may continuously try new actions while also preferring single (e.g., or chains of) actions that produce the largest cumulative reward.

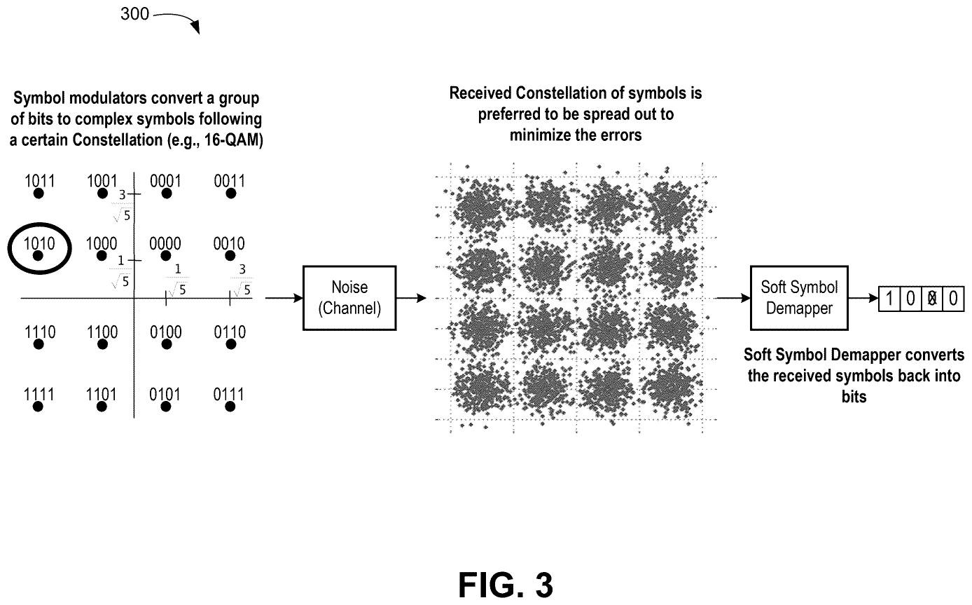

Constellation learning is considered herein. Symbol modulation and symbol demodulation are among the fundamental blocks of the physical (PHY) layer of wireless communications systems. As depicted in FIG. 3 at 300, symbol modulators can convert a group of bits to complex symbols that represent the in-phase and quadrature components of the baseband signal. Symbol demodulators can convert the received baseband complex signals to groups of bits that are fed into the channel decoder. The number of bits carried within a symbol depends on the modulation order of the modulation scheme. Examples of symbol modulation schemes include quadrature phase-shift keying (QPSK), quadrature amplitude modulation (QAM) (e.g., 16-QAM, 64-QAM, 256-QAM, 1024-QAM, etc.). In some examples, constellation shapes may be based on a square grid structure, such as for QPSK, QAM, etc. In some wireless communications systems, the constellations per modulation order and the corresponding MCS tables may be pre-defined.

FIG. 3 is a flow diagram showing an example visualization of a transmitted/received 16-QAM constellation, with 4 bits per symbol at 300. As shown in FIG. 3, soft symbol modulators may convert a group of bits to complex symbols following a certain constellation (e.g., 16-QAM). The symbols may be sent via a channel. Due to the effect of noise in the channel, received constellations of symbols are preferred to be spread out to minimize error. A soft symbol demapper may be used to convert the received symbols back into bits.

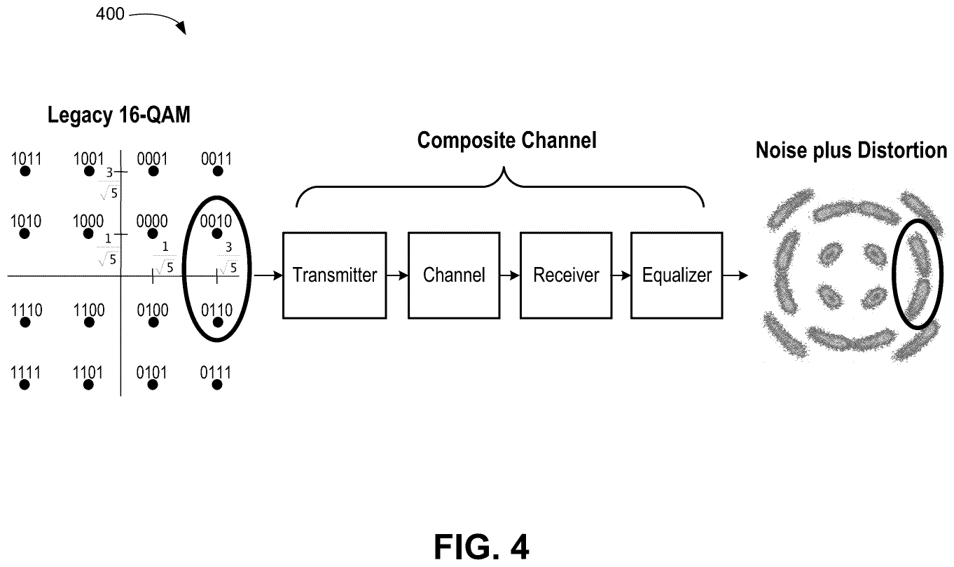

FIG. 4 is a flow diagram showing an example visualization of effects caused by noise and distortion on a 16-QAM constellation. As depicted in FIG. 4 at 400, the impact of transmitter and receiver impairments and imperfect equalization can cause a distortion that has a complicated effect on the received symbols. Some points in the constellation become more prone to error than others.

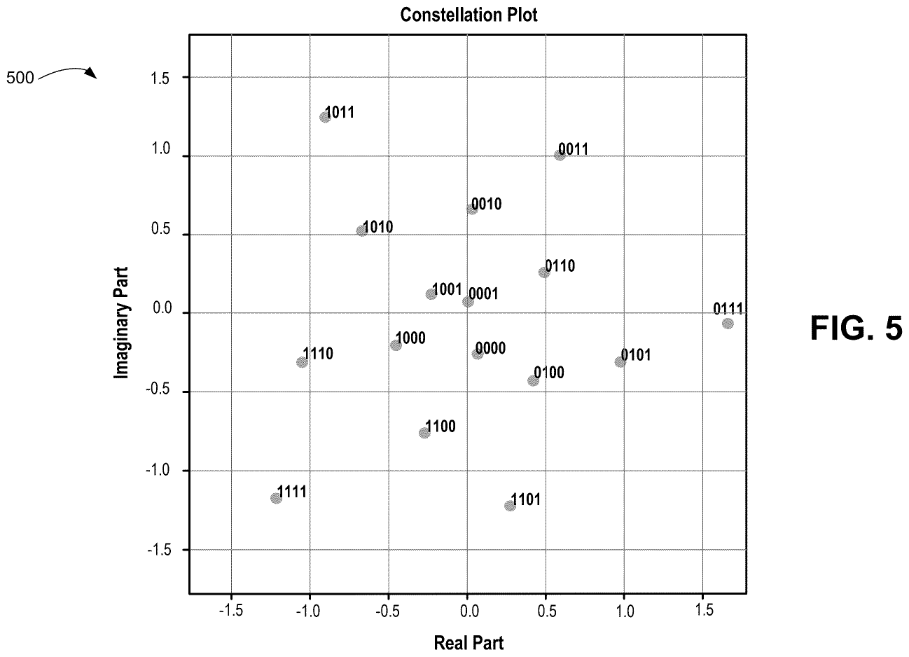

The performance of wireless communication systems depends on the choice of constellations. As shown above, the square QAM constellations are not optimal. The optimal constellation design depends on radio/hardware impairments and may vary over time and frequency. Learned constellations (e.g., using techniques like end-to-end learning) can improve the bit error rate and/or throughput performance through various hardware impairments. Examples of hardware/radio impairments include, but may not be limited to, power amplifier (PA) non-linearity (this disclosure), phase noise, I/Q imbalance, carrier frequency offset (CFO), etc.). The constellation learning is critical to compromise between performance, efficiency, and hardware requirements. An example of a learned constellation with modulation order 4 (e.g., 4 bits per symbol) under non-linear phase noise is given in FIG. 5 at 500. Using end-to-end learning schemes can dynamically train the mapper (e.g., which converts bits to symbols) and/or demapper (e.g., which converts received symbols to bits). Procedures to create and manage the learned constellations (e.g., mapper, de-mapper) are discussed herein.

FIG. 5 is a constellation plot showing an example visualization of a learned constellation diagram under non-linear phase noise at 500. The example of the learned constellation shown in FIG. 5 is a non-square constellation with modulation order 4 (e.g., 4 bits per symbol).

Power amplifiers (PAS) may be integrated in (e.g., 5G NR) wireless transmit/receive units (WTRUs) (e.g., User Equipment (UE)), and/or networks (NWs) to amplify the uplink signals to a desired transmit power level. A network (NW) can refer to any node in the network (e.g., gNB, another WTRU., Sidelink, WTRU-to-WTRU direct communication), etc. From a theoretical point of view, an ideal PA exhibits a linear behavior. For example, an ideal PA may scale the input signals to the desired transmit power without any distortions in phase or amplitude. However, real PAs may exhibit nonlinear behavior. For example, the transfer function between the input power and the output power for a real PA may be non-linear and become more non-linear close to the maximum output power of the amplifier (e.g., in or near the saturation region).

A PA operating near the saturation region introduces distortion into the output signals (e.g., amplitude compression and phase distortion). This is often referred to as amplitude-amplitude (AM-AM), amplitude-phase (AM-PM) distortion. To account for this behavior, a power backoff mechanism may be adopted that ensures linear PA operation at the cost of a lower power efficiency.

Using a power backoff mechanism may be particularly important for high peak to average power ration (PAPR) signals such as orthogonal frequency domain multiplexing (OFDM). However, using a power backoff mechanism may introduce a design decision tradeoff regarding efficiency vs linearity.

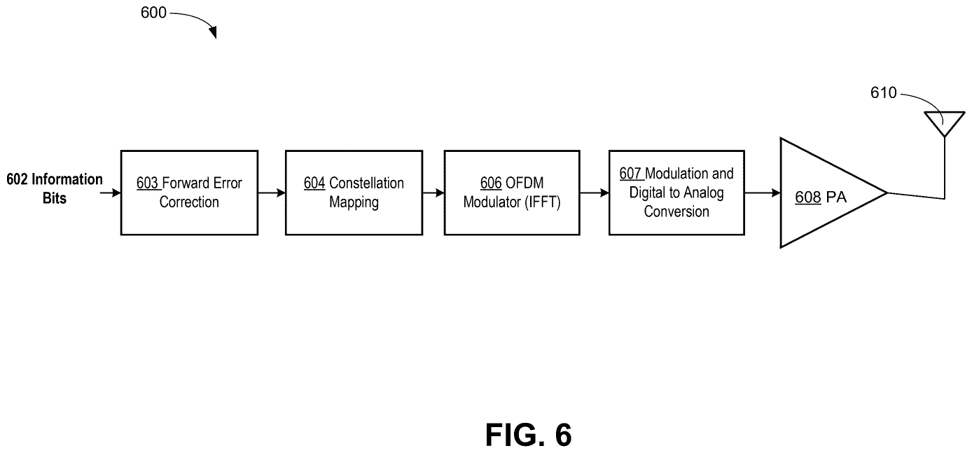

FIG. 6 is a block diagram showing an example of a typical transmit chain 600 in a wireless transmit/receive unit (WTRU). As shown in FIG. 6, the transmit chain 600 may take information bits 602 as input to 603 forward error correction and then as input to a constellation mapping function 604. The output from the constellation mapping function may be used as input for an OFDM modulator (e.g., inverse fast Fourier transform (IFFT)) 606. The output from the OFDM modulator 606 may be used as input 607 modulation and analog to digital conversion which is then used as input to a PA 608. The signal from the PA 608 may be transmitted via an antenna 610.

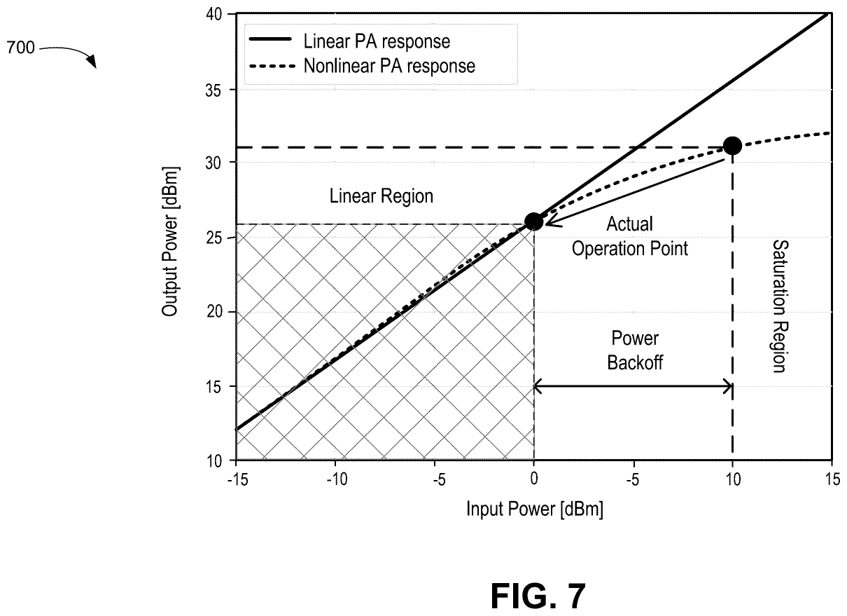

FIG. 7 is a graph showing an example of relationships between input power and output power for both a linear power amplifier (PA) response and a nonlinear power amplifier response at 700. FIG. 7 shows an example of an effect of a power backoff on PA operation.

Uplink Power Control is considered herein. Closed loop power control may be utilized in wireless communications systems for one or more channels. For example, closed loop power control is utilized in 5G for the physical uplink shared channel (PUSCH). Power control for the PUSCH is governed by the following equation.

$${P}_{PUSCH , b , f , c , k} ( i , j , {q}_{d} , l ) = min \{ \begin{matrix}{P}_{CMAX , f , c , k} ( i ) \\ \begin{matrix}{P}_{{O}_{PUSCH} , b , f , c} ( j ) + 10 {log}_{10} ( {2}^{μ} \cdot {M}_{RB , b , f , c}^{PUSCH} ( i ) + {α}_{b , f , c} ( j ) \cdot \\ {PL}_{b , f , c} ( {q}_{d} ) + {Δ}_{TF , b , f , c} ( i ) + {f}_{b , f , c} ( i , l )\end{matrix}\end{matrix} \}$$

The term f_{b,f,c}(i, l) determines the power control command from the Transmission Power Control (TPC). The first term is P_{O}_{_{PUSCH}}_{,b,f,c}(j) and is the target base receive power at the gNB. The second term,

$$10 {log}_{10} ( {2}^{μ} \cdot {M}_{RB , b , f , c}^{PUSCH} ( i ) )$$

is proportional to the number of resource blocks (RBs) in the PUSCH with power increasing with the number of RBs. The α_{b,f,c}(j) PL_{b,f,c}(q_{d}) term is the pathloss factor where transmit (Tx) power has to increase to compensate for increases in pathloss. The Δ_{TF,b,f,c}(i) term adjusts power according to the MCS.

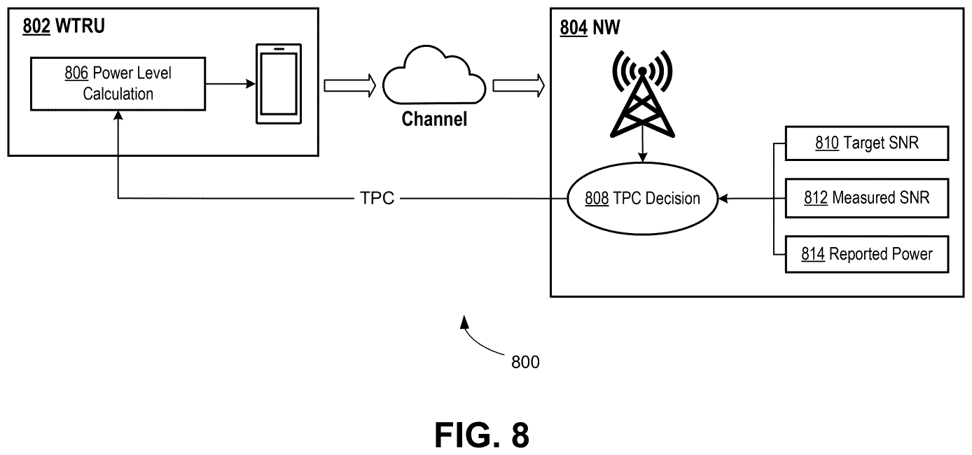

FIG. 8 is a system diagram illustrating an example of a system for closed loop power control with transmission power control messaging. As shown in FIG. 8, a WTRU 802 may send transmissions to a NW 804 via a channel. The NW 804 may make a TPC decision at 806. The TPC decision may be influenced by measurements of the transmission sent by the WTRU 802, as well as by other factors including a target signal to noise ratio (SNR) 810, a measured SNR 812, and/or a reported power 814. The NW 804 may send a TPC to the WTRU 802. The TPC may include a field indicating that the WTRU 802 should adjust its transmit power level, information, or fields for indicating whether the transmit power level should be increased or decreased, and/or information indicating the step size by which it should be increased or decreased. The WTRU 802 may make a power level calculation 806 and may send transmissions again to the NW 804 via the channel. This process may be repeated iteratively for one or more transmission, allowing the NW 804 to adjust the WTRU's 802 power level.

The traditional square QAM constellation has been widely used in communication systems, including 5G NR, due to its simple structure. For example, QPSK, QAM (e.g., 16-QAM, 64-QAM, 256-QAM, 1024-QAM, etc.) are examples of square constellations that have been adopted in cellular systems.

Apparatuses in wireless communications systems may use Power amplifiers (PAs) to amplify transmitted signals. PAs may exhibit nonlinear behaviors in gain and phase and may introduce distortions into the transmitted signals. For example, PAs integrated in 5G NR transmitters amplify the transmitted signals to the desired transmit power level and exhibit nonlinear operations in gain and phase that may induce distortions into the transmitted signals.

Some wireless systems may use OFDM waveforms. Due to high PAPR in OFDM, a large power backoff, and therefore a more powerful PA, may be used (e.g., as in the 5G NR transmitters) to ensure the PA operates in the linear region (e.g., no distortions or small distortions). Allowing the PA to operate in the non-linear region will allow for a greater SNR and consequently higher data rates for the same allocated resources.

Utilizing square QAM constellations may reduce performance in terms of throughput or required bandwidth when operating in low power backoff, since square constellations (e.g., QAM constellations) are not optimized to tolerate the induced distortions.

As described herein, choosing a learned constellation may optimize the system with respect to non-linearities in PA backoff in uplink.

A table (e.g., a 2-D table or 3-D table) of optimized constellation patterns for one or more configurable modulation orders or modulation and coding schemes (MCSs) in one dimension, for one or more configurable waveforms (e.g., cyclic prefix-orthogonal frequency domain multiplexing (CP-OFDM), discrete Fourier transform spread OFDM (DFT-s-OFDM), etc.) in one dimension, and/or for one or more (e.g., a list of) discrete PA backoff values in another dimension. The discrete PA backoff values can be stored after a learning phase. The PA backoff values may correspond to the WTRU transmit power level.

Based upon signaled MCS, configured waveform, and power control values, the transmit power can be determined for a given WTRU. A specific constellation pattern may be chosen by the WTRU based upon that backoff value, MCS, and/or waveform. The transmit power level can either be signaled to the gNB and/or estimated by the gNB.

Both the Tx and receive (Rx) sides need to have a known MCS, waveform indicator, and/or PA backoff value. In some wireless systems (e.g., 5G systems) the MCS value may be signaled (e.g., by the network to the WTRU) so the modulation order is known by both the network and the WTRU.

The WTRU can perform one of the following actions, so that the transmit power level and consequently the PA backoff value are known to the network. The WTRU may report the transmit power or PA backoff level frequently or whenever it changes. The WTRU may report the PA backoff level only periodically or if there are significant configuration changes. The WTRU may adjust the PA backoff level based on transmit power control (TPC) commands. The gNB or network may estimate the PA backoff level based upon TPC commands that are part of existing power control signaling.

Periodic signaling of the transmit power and/or PA backoff value may reduce overhead. In such cases, the transmit power can be estimated by the gNB.

Frequent signaling may allow for the exact value of the transmit power and/or PA backoff to be known. This may allow for the correct constellation to be chosen but, may increase overhead. With infrequent periodic signaling, the gNB can estimate the transmit power level (e.g., PA backoff level). The constellation pattern can be estimated by the gNB to align with transmit power calculations in the WTRU. This may reduce overhead, but may require additional calculations at the gNB side, for example.

To estimate the transmit power and/or PA backoff, the gNB may use the closed loop power control. The TPC field will indicate a change in transmit power. For example, the TPC field may indicate a −1, 0, +1, or +3 dB step in transmit power.

The gNB may assume the change in transmit power will correspond to the same step signaled in the TPC field assuming other parameters are held constant. If bandwidth part, pathloss or any other parameter changes, the PA backoff level can be resent.

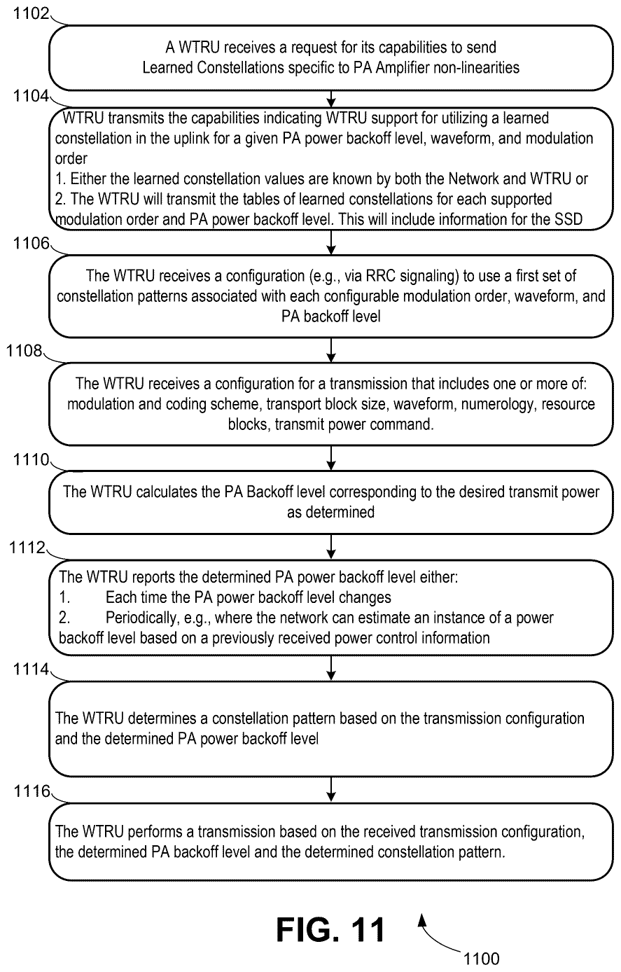

The procedures for enabling a Chosen Constellation for Optimizing non-linear regions of Transmit Power Amplifiers are detailed below and summarized in FIG. 11. The network (NW) can refer to any node in the network (e.g., gNB, another WTRU., Sidelink, WTRU-to-WTRU direct communication), etc.

In some cases, a WTRU may receive a request to transmit an indication of its capability to support learned constellations, and/or an indication of the type of power amplifier (PA) present in the WTRU.

In some cases, the WTRU may report its learned constellation capabilities. The learned constellation capabilities may include a first table of optimized constellation patterns (e.g., possibly including soft symbol demapper values) for one or more (e.g., each) configurable modulation order, waveform indicator, and associated PA backoff values corresponding to the Tx Power.

The WTRU may receive configuration information (e.g., via RRC signaling) which indicates the WTRU is to use a first set of constellation patterns associated with each configurable modulation order, waveform (e.g., CP-OFDM, DFT-s-OFDM, etc.), and/or PA backoff level.

The WTRU may receive configuration information for a transmission that includes one or more of: a modulation and coding scheme, a transport block size, a waveform (e.g., CP-OFDM, DFT-s-OFDM), a numerology, an indication of one or more resource blocks, and/or a transmit power command.

The WTRU may determine a PA backoff level based on the transmission configuration information. The WTRU may report the determined PA backoff level. The WTRU may also report the power transmitted per RB, for example, to allow the NW to calculate power backoff if the number of RBs are changed. The PA characteristics may be known at the NW. The WTRU may report the power transmitted per UL grant (e.g., or per UL transmission).

The WTRU may determine the PA backoff based, at least in part, on the number of RBs granted. The report including the determined PA backoff may be associated with a particular UL transmission (e.g., indicated in the report or in the report request). Additionally, or alternatively, the report may indicate a per RB power level and/or a PA saturation value (e.g., or other reference) value. The PA saturation (e.g., or other reference) value might not change (e.g., or might not frequently). Thus, the PA saturation (e.g., or other reference) value may be signaled in a different message such as in the WTRU capabilities information message

The WTRU may be triggered to report the determined PA backoff level, for example: each time the PA backoff level changes, and/or periodically. In examples, the network can estimate an instance of a power backoff level based on a previously received periodic backoff level and/or the transmit power control (TPC) information that has been sent since the last PA backoff level was received.

The WTRU may determine a constellation pattern based on the transmission configuration and/or the determined PA backoff level. The WTRU may perform a transmission based on the received transmission configuration, the determined PA backoff level, and/or the determined constellation pattern.

In some examples, to estimate the WTRU transmit power and/or power backoff in cases where the Tx Power or PA backoff is periodically reported (e.g., only periodically reported) and not always known, the gNB may use the Closed Loop Power control TPC bits. For example, the TPC field may indicate a −1, 0, +1, or +3 dB step. The estimated PA backoff level can be calculated by adding the step size to the previous value. In addition, the updates to the value can be made based upon changing bandwidth part (BWP) and/or UL grant size (e.g., number of RBs used) and/or pathloss estimation. The closest table value for the PA backoff can be used by the gNB to determine the constellation pattern. The closest PA backoff level on the table may be chosen.

For a used waveform, the estimated PA backoff may be used to compute an index into a table or used as input to a mapping function by the gNB to determine a constellation pattern. The chosen pattern may be used to demodulate the received signal or to choose the soft symbol demapper (SSD) to demodulate the signal. The backoff levels may or may not be stored with a constant step size. The gNB can assume the corresponding step in the PA backoff assuming other parameters are held constant.

Apparatuses in wireless communications systems may be configured for learning optimized constellations for uplink transmission to compensate for non-linear PA behaviors.

Constellation learning may improve the end-to-end system performance (e.g., BER, BLER, throughput) of a wireless communication system, by adapting to the hardware/radio impairments (e.g., nonlinear PA behavior), as well as dynamic channel conditions. The apparatuses, steps, and procedures discussed herein enable transmitter-side training for online constellation learning in uplink, while taking nonlinear PA behavior in the WTRU into account.

A WTRU configured as a transmitter may receive configuration information comprising a set of initial constellations (e.g., square QAM, non-square QAM). The WTRU may inform the NW which PA power backoff will be used. Afterwards, the WTRU may use uplink training bits (e.g., data bits, pseudo-random data bits) to create the modulated symbols, which are transmitted over-the-air to the NW. By using the uplink training bits, the NW may calculate the gradients and/or learned constellation performance metrics (e.g., AIML model loss, BER, BLER, throughput, etc.), then sends one or more of them to the WTRU as online constellation learning feedback. The WTRU may train the constellation through online constellation learning feedback and report the learned constellation to the NW. The WTRU and/or the NW may store the learned constellation with the corresponding PA power backoff.

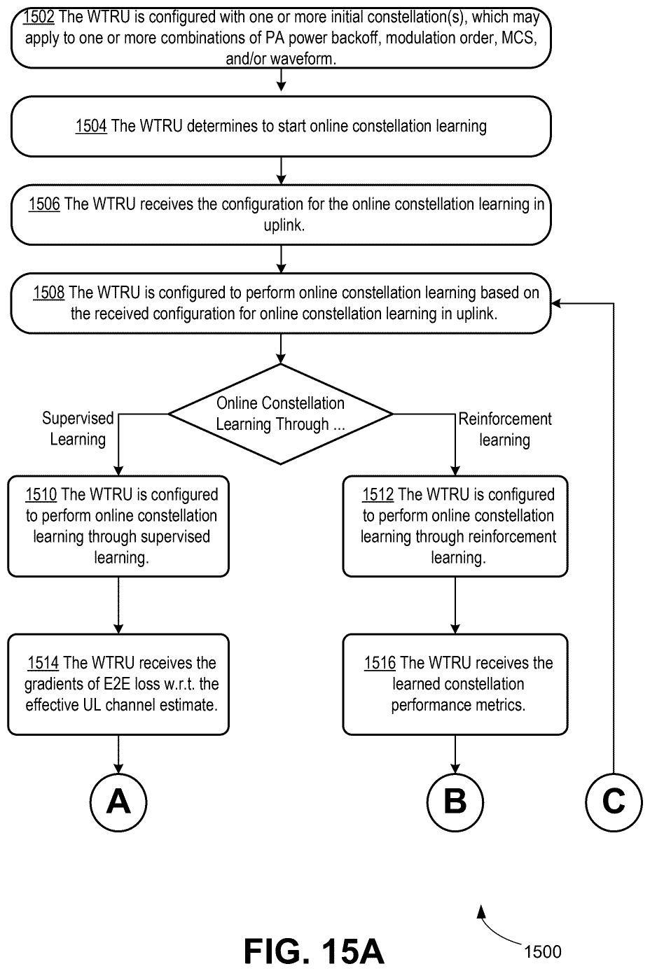

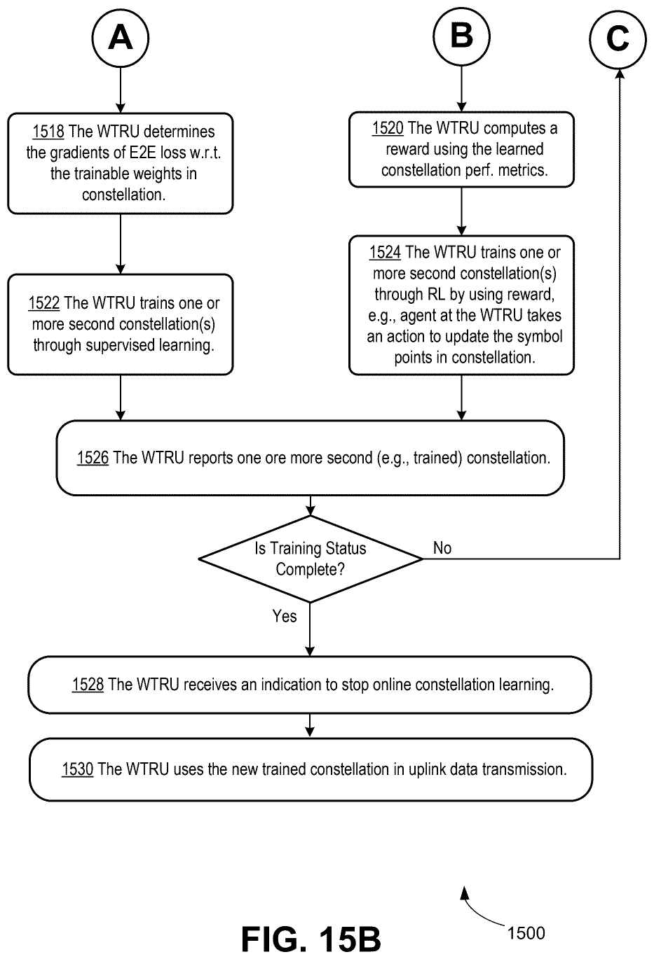

Example procedures for enabling the transmitter-side training for online constellation learning in the uplink are detailed below and summarized in FIG. 15A and FIG. 15B. The NW can refer to any node in the network (e.g., a gNB, another WTRU, such as a Sidelink device using a WTRU-to-WTRU direct communication, etc.).

In examples, a WTRU may receive (e.g., from NW) a request to transmit its AIML capabilities. The WTRU may transmit an indication of its AIML capabilities to the NW. The WTRU may transmit its capabilities message to the NW by means of RRC signaling, for example.

The capabilities message may indicate one or multiple of the following. The capabilities message may indicate whether the WTRU has support for AIML-based constellation learning. The capabilities message may include information about any of the WTRU's hardware/radio characteristics or impairments. For example, the capabilities message may include information on the WTRU's PA characteristics, etc. The information on the WTRU's PA characteristics may comprise the PA linear power range. The PA characteristic may include a model or the parameters of a model of the PA (or PAs) used by the WTRU transmitter.

The WTRU may be configured (e.g., through RRC signaling) with information for one or more initial constellation(s). The one or more initial constellations may apply to one or more combinations of PA power backoff, MCS, modulation order, and/or waveform indicator. For example, WTRU may be configured with an initial constellation diagram for each modulation order, MCS, and/or waveform (e.g., CP-OFDM, DFT-s-OFDM).

The WTRU may be configured with information for multiple initial constellation diagrams. For example, the WTRU may be configured with a single constellation diagram per sub-band, per Precoding Resource Block Group, RB set, or per layer.

For example, the first sub-band may be associated, via the configured information, with a constellation with 16 symbols (e.g., 4 bits per symbol), while the second sub-band is configured with a constellation with 64 symbols (e.g., 6 bits per symbol).

The configured information for the initial constellation diagrams may include but is not limited to one or more of the following. The information for the initial constellation diagrams may comprise a previously trained/learned constellation under a similar condition (e.g., similar channel conditions, similar PA power backoff, hardware/radio impairments, selected waveform, etc.). The information for the initial constellation diagrams may comprise a constellation that was trained/learned during online constellation learning iterations. The information for the initial constellation diagrams may comprise a square QAM constellation for the first iteration of online constellation learning.

The WTRU may determine to start online constellation learning. In examples, the WTRU may be triggered to initiate constellation learning. Triggers to initiate constellation learning include, but are not limited to, one or more of the following.

The WTRU may be triggered to initiate constellation learning when it receives a command/message triggering online constellation learning. The WTRU may be triggered to initiate constellation learning when it is configured to use AIML for constellation learning (e.g., for a first time). The WTRU (e.g., or the NW) may be triggered to initiate constellation learning when it detects a need to initiate constellation learning.

Examples of detectable conditions that may indicate a need to initiate constellation learning include but are not limited to the following. The WTRU or NW may detect a need to initiate constellation learning based on AIML models drift detection mechanisms at the WTRU and/or the NW which indicate that the AIML models have drifted or are drifting. The AIML models drift may be caused, for example, by PA characteristics changing over time (e.g., PA aging).

The WTRU or NW may detect a need to initiate constellation learning based on the WTRU entering a geographic region or a cell (e.g., indicated by a new cell ID or a new registration area) for which the constellation has not been previously trained. In examples, the WTRU may detect a need to initiate constellation learning based on connecting to a cell that it has not previously connected to, a cell in which it has not previously trained a constellation for, or a cell which it has not connected to for a period of time greater than a threshold. In examples, the WTRU may compare GPS coordinates (e.g., compare a current GPS coordinate with a GPS coordinate associated with a trained constellation) to measure distance to previously trained regions. If distance is above a threshold provided by the NW, the WTRU may signal the NW indicating the threshold is exceeded, and possibly the distance and the current location.

The WTRU or NW may detect a need to initiate constellation learning based on a periodic or aperiodic timer. In examples, the training for the online constellation learning can be periodic, aperiodic, and/or semi-persistent.

The WTRU may receive configuration information for the online constellation learning in uplink. The configuration information may comprise, but is not limited to, one or more of the following.

The configuration information may comprise online constellation learning training allocations. Online constellation learning training allocations may include a set of PUSCH resource elements (REs) on which the WTRU may transmit the symbols modulated by uplink training bits. The uplink training bits may include but are not limited to: Pseudo-random data bits generated through a seed; and/or any other form of data bits, or bits derived from data bits. If pseudo-random data bits are used, the WTRU/NW may send an indication of the seed bits to the NW/WTRU, to enable both the WTRU and NW to generate the pseudo-random data bits for training. If pseudo-random or non-pseudo random data bits are used, the WTRU and NW may share the training data (e.g., in the configuration information or a response thereto), so that both the NW and WTRU have the training data for training purposes.

The configuration information may comprise training related information, which includes, but is not limited to one or more of the following. The training related information may include seed(s) to generate the uplink training bits at the WTRU. The training related information may include seed(s) to generate pseudo-random perturbations for creating perturbations for groups of REs. The training related information may include information which indicates that one or more groups of REs are associated with one or more perturbations. The training related information may include modulation and coding schemes (MCSs) to apply to the training bits. The training related information may include a set of code rates for forward error correction (FEC) (e.g., low-density parity checking (LDPC)). In examples, the training related information may indicate a code rate for each configured constellation, and/or a fixed code rate for all configured constellations. In examples, the training related information may comprise a waveform to be employed (e.g., CP-OFDM, DFT-s-OFDM, etc.).

The configuration information may comprise a transmit power and PA power backoff level to be used. The configuration information may comprise an indication of a downlink resource allocation to receive the online constellation learning feedback (e.g., feedback such as rewards, gradients and/or learned constellation performance metrics.). For example, the WTRU may receive the gradients of the end-to-end loss function with respect to the effective uplink channel estimate on the downlink resources, (e.g., signal by DCI or MAC-CE). For example, the WTRU may receive one or more constellation performance metric(s) for one or more configured constellation(s) on downlink resources, (e.g., signaled by DCI or MAC-CE). The constellation performance metrics may include BER, BLER, throughput, AIML model loss, etc.

The configuration information may comprise an indication that the WTRU is to learn a constellation. For example, the configuration information may indicate that the WTRU is to learn a constellation for one or more (e.g., each) modulation orders greater than 2 bits/symbol through the range configured by SNRₘᵢₙ and SNRₘₐₓ for each modulation order, waveform indicator, and/or PA power backoff range.

For example, the configuration information may indicate that the WTRU is to learn a constellation for each modulation order and code rate (e.g., per MCS) through the range configured by SNRₘᵢₙ and SNRₘₐₓ, for each MCS (e.g., learning the constellations for a range of SNR in a given MCS).

For example, the configuration information may indicate that the WTRU is to learn a constellation for each combination of MCS (e.g., with its associated SNR range), waveform (e.g., CP-OFDM, DFT-s-OFDM, etc.) and hardware/radio impairment class (e.g., PA power backoff) through the range configured by SNRₘᵢₙ and SNRₘₐₓ for each MCS and partitioned channel BW (e.g., sub-band) with a common class of hardware/radio impairments. The WTRU may perform online constellation learning based on the received configuration information for online constellation learning in the uplink.

The WTRU may be configured to perform online constellation learning through supervised learning. The WTRU may receive the gradients of the end-to-end loss function with respect to the effective uplink channel estimate computed by the NW as online constellation learning feedback. The WTRU may determine the gradients of end-to-end loss function with respect to the trainable weights in the constellation model by using the online constellation learning feedback. The WTRU may train one or more second constellation(s) through supervised learning by using the gradients of end-to-end loss and/or the trainable weights. For example, the WTRU may use a learning algorithm to update the trainable weights based on the gradients (e.g., stochastic gradient decent (SGD), adaptive moment estimation (ADAM), and root mean square propagation (RMSProp)).

Additionally, or alternatively, the WTRU may be configured to perform online constellation learning through reinforcement learning. The WTRU may receive the learned constellation performance metrics computed by the NW as online constellation learning feedback. The WTRU may compute a reward by using the received learned constellation performance metrics. In examples, the reward may be a vector constructed from the received learned constellation performance metrics associated with each perturbation (e.g., mean AIML model loss over all REs with the same perturbation). The WTRU may train one or more second constellation(s) through reinforcement learning by using reward. For example, the reinforcement learning agent at the WTRU may take an action to update the symbol points in the learned constellation. For example, the reinforcement learning agent at the WTRU may apply a perturbation vector to the constellations representing the action of reinforcement learning agent. The perturbation vector may include the perturbations for each symbol point in the learned constellation (e.g., 2M values for M-QAM).

The WTRU may report one or more second (e.g., trained) constellation(s) to the NW. In examples, the reporting can be transmitted as uplink control information (UCI) on a physical uplink control channel (PUCCH) and/or a physical uplink shared channel (PUSCH), as MAC-CE, or as RRC signaling.

The WTRU may receive an indication to stop online constellation learning (e.g., training is complete).

The WTRU (e.g., and the NW) may store the learned constellation for the corresponding MCS, waveform indicator, hardware/radio impairments class (e.g., including PA power backoff level), and/or the SNR range used during training. In some cases, the WTRU may use offline training during an offline training period to enable learning of the more optimal constellation pattern for each PA backoff and modulation value. In some cases, during training, to keep Rx power in a required range, a variable attenuation or increased physical distance can be used to compensate for PA backoff being reduced.

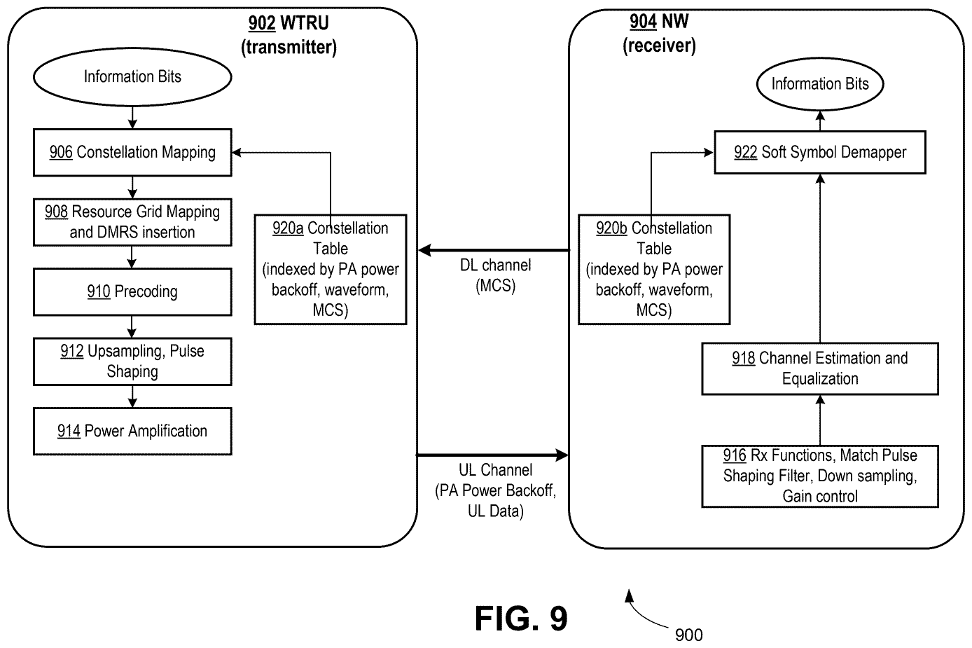

FIG. 9 is a block diagram showing an example of signaling for a learned constellation based upon PA backoff. As shown in FIG. 9, a WTRU 902 may perform constellation mapping 906 of information bits. This may be done using a constellation table 920a. The constellation table 920a may be indexed by PA power backoff, waveform indicator, and/or MCS. After constellation mapping 906, the WTRU 902 may perform 908 resource grid mapping and DMRS insertion. Next, the WTRU 902 may perform precoding 910, and then up sampling and/or pulse shaping 912. At 914, the WTRU 902 may perform power amplification 914. The WTRU 902 may transmit the signal (e.g., comprising UL data) using a UL channel (e.g., using a PA power backoff). The NW 904 may receive the signal, and at 916, perform one or more of: Rx functions, match pulse shaping filter, down sampling and/or gain control. At 918, the NW 904 may perform channel estimation and/or equalization. The NW 904 may use a soft symbol debugger 922 (e.g., with input from a constellation table 920b) to obtain the information bits.

As discussed herein, a system or apparatus may use a learned constellation (e.g., for communications).

The ability to utilize a learned constellation (e.g., as opposed to a pre-configured square constellation) depends upon both the gNB and WTRU having access to information about points in the constellation, and/or soft symbol demapper information.

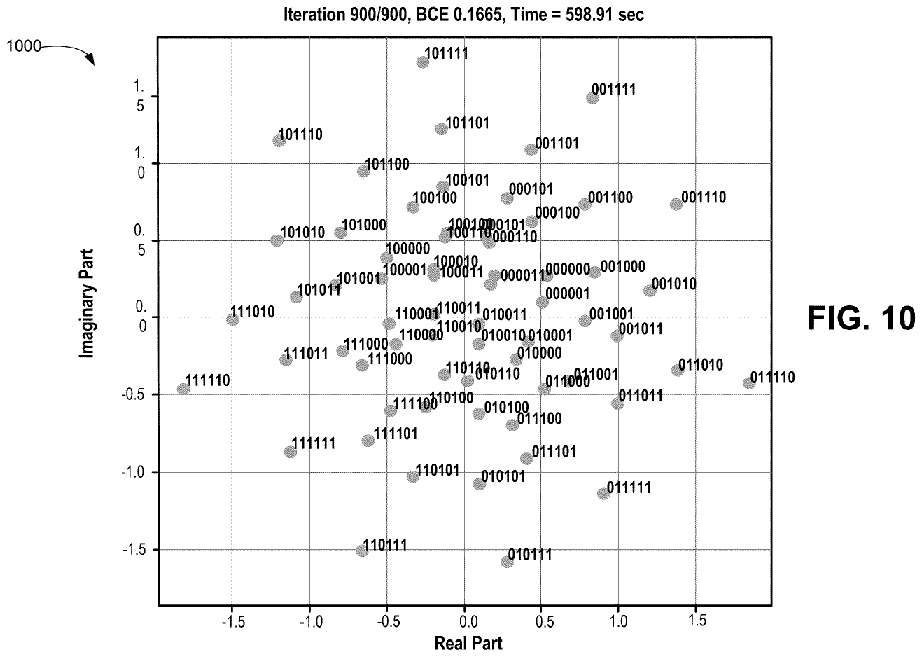

FIG. 10 is a constellation plot showing an example of a bit mapping of a learned 64-QAM constellation at 1000. The constellation plot shown in FIG. 10 is a non-square constellation.

The information about points in the constellation may include a bit mapping and/or in-phase/quadrature (I/Q) position for one or more points (e.g., each point) in the constellation. For example, for a N-QAM constellation with N points, there may be a table of N complex values where the index 0 to N−1 corresponds to the binary pattern of each point and the complex value indicates the coordinates of the constellation point in the I/Q plane.

The soft symbol demapper information may include Log Likelihood Ratios (LLRs) which measure the likelihood or confidence in each bit's value, and/or means for calculating the LLRs. Since each point on the constellation may represent multiple bits, the probability of each bit being decoded as a 1 or 0 may be evaluated.

A WTRU may be configured to perform a capability exchange for constellation learning. The NW may initiate a WTRU capability exchange process, for example, by sending a WTRU Capability Enquiry RRC message (e.g., UECapabilityEnquiry) to the WTRU. This message can be used to request specific information regarding the WTRU's capabilities. The NW may include parameters in this message to specify one or more capabilities it is interested in. The NW may specify parameters related to WTRU's capability in supporting learned constellations in uplink (e.g., for compensating the non-linearities in PA backoff) in a WTRU Capability Enquiry message (e.g., the capability of choosing a learned constellation based upon MCS and known or estimated PA backoff value).

Upon receiving the WTRU Capability Enquiry RRC message, the WTRU may respond with a WTRU Capability Information RRC message (e.g., UECapabilityInformation) accordingly. This message may include detailed information about the WTRU's capabilities. Parameters related to the AIML functions that may be requested and/or provided during the WTRU capability exchange process between the WTRU, and the NW include, but are not limited to, the following.

During the capability exchange process, the NW may request and/or the WTRU may provide an indicator of whether reporting hardware and/or radio impairments (e.g., PA characteristics, PA linear power range, PA power backoff etc.) is supported or not. During the capability exchange process, the NW may request and/or the WTRU may provide an indicator of whether choosing a learned constellation based upon MCS, waveform indicator, and (e.g., known or estimated) PA backoff value. During the capability exchange process, the NW may request and/or the WTRU may provide an indicator of whether signaling of PA backoff level (e.g., each time it changes) is supported or not. During the capability exchange process, the NW may request and/or the WTRU may provide an indicator of whether periodic signaling of PA backoff level is supported or not. During the capability exchange process, the NW may request and/or the WTRU may provide an indicator of whether using one or more learned constellation (e.g., non-square QAM) is supported or not.

The NW and the WTRU may exchange configuration information for constellation learning. If the network and the WTRU both support learned constellations for uplink, each side may be configured with tables of constellation values for each supported modulation order (e.g., 16, 64, 256 or 1024). For each supported modulation order, there may be learned constellations for specific PA backoff levels in dB and/or specific waveform (e.g., CP-OFDM, DFT-s-OFDM, etc.). The discrete supported backoff levels can be evenly spaced in dB or stored with any other method (e.g., logarithmic spacing, etc.) so that the nearest value to the current PA backoff level can be used. The closest PA backoff level in dB that is listed in the table to the utilized PA backoff level used to transmit at the WTRU may be used.

For each modulation order, waveform indicator, and PA backoff level, the table may comprise the I/Q complex value of the position of one or more constellation points (e.g., each constellation point) in the complex plane and/or the associated bit mapping. The associated bit mapping may comprise a binary value of length log₂ (N) where N is the number of points in the constellation. The associated soft symbol demapper (SSD) information may be stored along with each learned constellation.

For encoding the uplink Physical Uplink Shared Channel (PUSCH), the WTRU may load the constellation pattern based upon the Modulation order, the waveform indicator, and closest PA backoff level from the table. The bit mapping and coding will utilize the learned constellation pattern to generate the OFDM signal.

The gNB on the network side may use the corresponding SSD to decode the signal and map the received signal to soft symbols to be decoded. In some wireless communications systems (e.g., 5G), for a given MCS value configured by the network for the WTRU, the WTRU will use a square QAM constellation.

The NW and/or the WTRU may engage in signaling for constellation learning WTRUs that support learned constellations may need to be queried by the network as to their capabilities. For example, during the Initial Attach Procedure the network and WTRU may exchange capability information. The WTRU may respond to a WTRU Capability Enquiry message with a WTRU Capability Information Response.

The WTRU Capability Information Response may include an indication of whether learned constellations are supported. If Learned Constellations are supported, the WTRU may report the supported learned constellation values and/or the Soft Symbol Demapper Values to the network. Additionally, or alternatively, the constellation values for the given PA amplifier may already be known by the network, for example, stored in a set of tables. In such cases, the WTRU may indicate to the NW which table to use.

FIG. 11 is a flow chart showing an example of a WTRU procedure for using a learned constellation for physical uplink shared channel (PUSCH) transmission at 1100. In the example shown in FIG. 11, the procedure begins when a WTRU receives a request for its capabilities to send learned constellations specific to PA non-linearities at 1102. At 1104, the WTRU transmits an indication of the requested capabilities, indicating support for utilizing a learned constellation in the UL for a given PA power backoff level, waveform indicator, and modulation order. The learned constellation values may be known by both the NW and the WTRU. Additionally, or alternatively, the WTRU may transmit the tables of learned constellations for each supported modulation order, waveform indicator, and PA backoff level, along with information for the SSD.

At 1106, the WTRU may receive a configuration (e.g., via RRC signaling) to use a first set of constellation patterns associated with each configurable modulation order, waveform indicator, and PA backoff level). At 1108, the WTRU may receive a configuration for a transmission that includes one or more of: modulation and coding scheme, transport block size, waveform, numerology, resource blocks, transmit power command.

At 1110, the WTRU may calculate the PA power backoff level corresponding to the desired transmit power as determined. At 1112, the WTRU may report the determined PA power backoff level. The WTRU may report the determined PA power backoff level each time the PA power backoff level changes. The WTRU may report the PA power backoff level periodically (e.g., where the network can estimate an instance of a power backoff level based on a previously received power control information).

At 1114, the WTRU may determine a constellation pattern based on the transmission configuration and/or the determined PA power backoff level. At 1116, the WTRU may perform a transmission based on the received transmission configuration, the determined PA power backoff level, and/or the determined constellation pattern.

The WTRU and/or the NW may perform learning of optimized constellations for uplink transmission (e.g., to compensate for non-linearities in PA behavior).

Constellation learning may improve the end-to-end system performance (e.g., BER, BLER, throughput) of a wireless communication system, by adapting to the hardware/radio impairments, including the non-linearities in PA behavior, as well as dynamic channel conditions. Constellation learning can be performed either offline or online. Learning the constellation can be performed offline using standardized and/or agreed models for the PA. For example, a standardized and/or agreed model for the PA may be based on a simulation-based polynomial (e.g., a 9th order polynomial) or other mathematical description mapping the input signal into the output signal.

PA models (e.g., a polynomial or a rational function) may be differentiated from the parameters associated with the PA models. Some PA models may be better suited to particular PA architectures. For example, a Traveling Wave Tube (TWT) PA and a millimeter wave (mmW) Silicon Germanium (SiGe) class-AB PA may be best described or approximated by different models but could also be described or approximated by the same model using different parameters.

One or more than one model may be used to describe the same PA. In one example of offline training via simulation, the PA manufacturer may provide one or more parameterized models for each PA or for each wafer of PAs or for PAs produced by different fabs or using different process design kits (PDKs) etc. A simulation can be run to train a constellation, a demapper, and/or a neural receiver offline.

For example, the NW may request the WTRU to indicate a list of models that it has for its PA(s) or may search a database for the same based on a PA identification information (e.g., a PA identification number) that may be signaled to the NW. The NW may then indicate which PA model it will use and request parameters for that PA model. The NW (e.g., or a cloud/edge app) may then run a simulation to determine the best constellation(s), demappers, and/or neural receivers to use for each waveform, modulation order, MCS, and/or power level or PA backoff level. The NW may then signal the WTRU the constellations to use for those different cases.

The NW may also have the corresponding demappers and/or neural receivers to use for each waveform, modulation order, MCS, and power level or PA backoff level. Once confirmed, the NW may indicate to the WTRU when to start using the new constellations. For example, the NW may signal the WTRU to start using the new constellations at a signaled System Frame Number (SFN) and possibly for a given duration. The given duration may, for example, be given as a number of frames, and/or the duration may continue until a triggering event occurs. A triggering event, for example, could be a handoff or detection that the constellation(s) are not performing as well as expected etc.

For the case where the constellation is learned online, the training can be performed either at the transmitter (e.g., the WTRU), or the receiver (e.g., the NW). For transmitter-side training (e.g., the WTRU) for online constellation learning in UL, the constellation may be trained and updated at the WTRU based on training information (e.g., gradients and/or learned constellation performance metrics such as AI/ML model loss, BER, BLER, throughput, etc.) computed at the NW and signaled to the WTRU from the NW.

For receiver-side training (e.g., the WTRU) for online constellation learning in UL, the constellation may be trained and updated at the NW based on training information (e.g., gradients and/or learned constellation performance metrics such as AI/ML model loss, BER, BLER, throughput, etc.) computed at the NW. The NW may signal the updated constellation to the WTRU. In this case, PA models and associated parameters may still be signaled as in the offline case to be used as side information. Alternatively, the PA models and associated parameters may not be shared. Additionally, during online training or during other dedicated sessions, the signals received from the WTRU may be used to verify or measure PA models and associated parameters. Based on the measurements, the NW may decide to signal new parameters of the model to WTRU and/or PA model database (e.g., if the difference between the estimated parameters and previous parameters exceed a threshold). This may also trigger another round of offline simulation based training.

Transmitter-side training for online constellation learning is discussed herein. Online constellation learning for uplink can be performed at the transmitter side (e.g., the WTRU). This may be referred to as transmitter-side training. Transmitter-side training may take non-linear behavior in the power amplifier of the WTRU into account.

In transmitter-side training, the NW (e.g., the receiver) may send configuration information to a first a WTRU (e.g., the transmitter). The configuration information may comprise a set of initial constellations (e.g., square QAM, non-square QAM). The WTRU may inform the NW which PA power backoff will be used. The WTRU may use the uplink training bits (e.g., data bits, pseudo-random data bits) to create the modulated symbols, and transmit the modulated symbols over-the-air to the NW. By using the uplink training bits, the NW may calculate the gradients of a loss function and/or learned constellation performance metrics (e.g., AIML model loss, BER, BLER, throughput, etc.), then sends one or more of them to the WTRU as online constellation learning feedback. The WTRU may train the constellation through online constellation learning feedback and report the learned constellation to the NW. The WTRU and/or the NW may store the learned constellation with the corresponding PA power backoff.

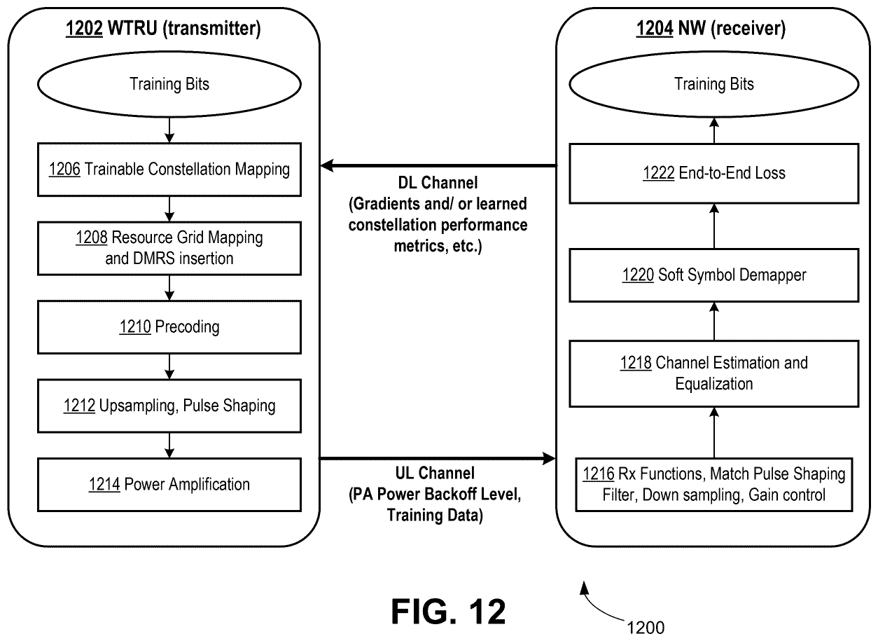

FIG. 12 is a block diagram showing an example of signaling for transmitter-side training for constellation learning in uplink communications. In the example shown in FIG. 12, the WTRU (e.g., transmitter) 1202 may begin with training bits. The WTRU 1202 may perform constellation mapping using a trainable constellation at 1206 using the training bits. At 1208, the WTRU 1202 may perform resource grid mapping and DMRS insertion. At 1210, the WTRU 1202 may perform precoding. At 1212, the WTRU 1202 may perform up sampling and/or pulse shaping. At 1214, the WTRU 1202 may perform power amplification. The WTRU 1202 may transmit the signal via a downlink channel. The WTRU 1202 may also send an indication of the PA power backoff, and/or the training data used.

The NW 1204 may receive the signal, along with the indication of the PA power backoff level and/or training data. At 1216, the NW 1204 may perform Rx functions, match pulse shaping filtering, down sampling, and/or gain control. At 1218, the NW 1204 may perform channel estimation and/or equalization. At 1220, the NW 1204 may use a soft symbol demapper. At 1222, the NW 1204 may compute the end-to-end loss (e.g., using the training data) and may recover the training bits. The NW 1204 may send, via a downlink channel, an indication of the gradients and/or learned constellation performance metrics, etc., to the WTRU 1202. The WTRU may update the trainable constellation mapping function 1206. This process may be repeated until training is complete (e.g., when the loss function is below a threshold).

Receiver-side training for online constellation learning is discussed herein. Online constellation learning for uplink can be performed at the receiver side (e.g., the NW). This may be referred to as receiver-side training. Receiver-side training may take non-linear behavior in the power amplifier (PA) of the WTRU into account.

In receiver-side training, the NW (e.g., the receiver) may send configuration information to the WTRU (e.g., transmitter). The configuration information may comprise one or more initial constellation(s) (e.g., square QAM, trained/pre-trained non-square QAM). For the receiver-side training for online constellation learning, the WTRU (e.g., transmitter) may generate (e.g., based on seed values) the uplink training bits (e.g., data bits, pseudo-random data bits, etc.) to create the modulated symbols, which are transmitted over-the-air to the NW (e.g., receiver). By using the uplink training bits, the NW may calculate learned constellation performance metrics (e.g., AIML model loss, BER, BLER, throughput, etc.). Then, the NW may train one or more second constellation(s) (e.g., through reinforcement learning) by using the learned constellation performance metrics. Later, the NW may transmit the one or more second (e.g., trained) constellation(s) to the WTRU.

AIML may be used for optimizing constellations. The constellation learning may be a function that is based on two AIML models, one residing at the WTRU, and one residing at the NW. Both AIML models may be configured to compensate for the non-linear behavior in the PA. The AIML model residing at the WTRU, referred to as a constellation (e.g., or constellation mapper), maps the information bits at the WTRU to complex constellation symbols to be transmitted to the NW through the uplink transmission chain (e.g., resource mapping, precoding, etc.). On the other hand, the AIML model residing at the NW, referred to as the soft symbol demapper, maps the equalized complex symbols from the WTRU to log likelihood ratios (LLRs) (e.g., or hard bits), which can be then converted back to information bits. The stages of the AIML process are discussed below.

Applications may be used for online constellation learning. Online constellation learning may, in examples, be initiated via an application. For example, an application hosted at the WTRU and/or NW may initiate online constellation learning. Online constellation learning may occur in stages. A first stage of the online constellation learning may be referred to as the application stage.

Online constellation learning processes may include an input stage. Input data for a constellation mapper may include but is not limited to one or more of the following: uplink data bits, an indication of a transmit power, and/or an indication of a PA backoff level.

Input data for a soft symbol demapper may include, but is not limited to equalized complex symbols at the NW, and/or an estimated noise power at the NW. The estimated noise power at the NW can be also part of the AIML model input.

Online constellation learning processes may include a preprocessing stage. For the constellation mapper, (e.g., optional) preprocessing for the constellation may comprise applying channel encoding to the uplink training bits. For the soft symbol demapper, preprocessing may comprise concatenation of the real and imaginary parts of the complex symbols to obtain the real-valued input to the AIML model.

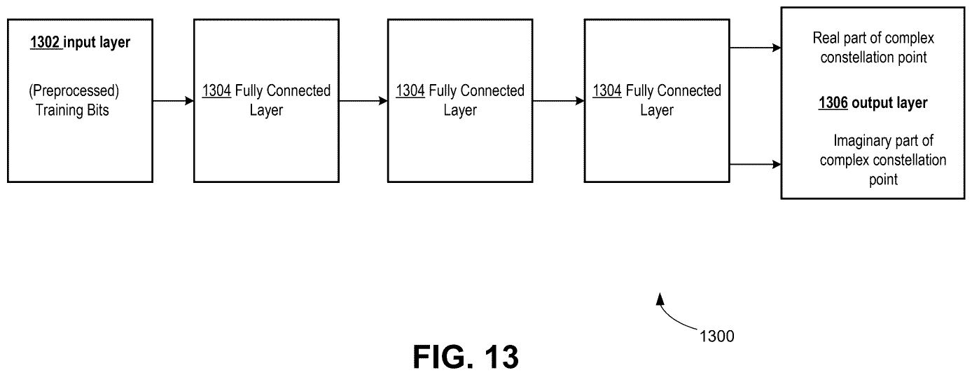

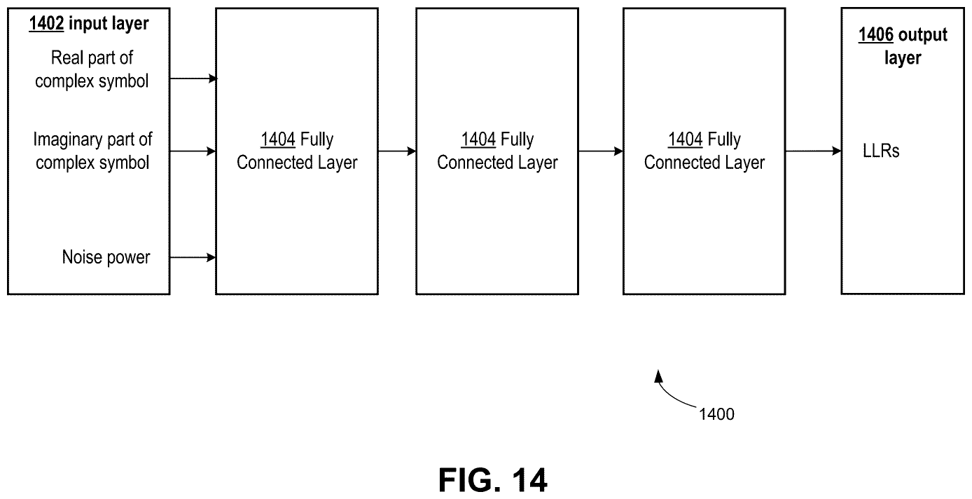

Online constellation learning processes may include an AIML model stage. Examples of AIML models for constellation learning are shown in FIG. 13 and FIG. 14.

An example of an AIML model for the constellation mapper is depicted in FIG. 13 at 1300. FIG. 13 is a block diagram showing an example of an architecture for an artificial intelligence or machine learning (AIML) based constellation mapper. The example AIML model shown in FIG. 13 comprises an input layer 1302, multiple fully connected layers 1304, and an output layer 1306.

An example AIML model for the soft symbol demapper is depicted in FIG. 14. FIG. 14 is a block diagram showing an example of an architecture for an AIML based soft symbol demapper at 1400. of the Example shown in FIG. 14 comprises an input layer 1402, multiple fully connected layers 1404, and an output layer 1406.

Online constellation learning processes may include an output data stage. For a constellation mapper, assuming that the constellation to be learned has an order of M, (e.g., M constellation points), the input to the AIML model may be a codeword with √M bits. The output of the AIML may be the real and imaginary parts of the constellation point associated with the input codeword.

For a soft symbol demapper, assuming that the constellation to be learned has an order of M, (e.g., M constellation points), the inputs to the AIML model may be the real and imaginary parts of the received equalized symbol at the WTRU along with an estimate of the noise power at the WTRU. The output of the AIML may be the √M LLRs associated with the √M bits of the original codeword input to the constellation mapper.

Online constellation learning processes may include a training stage. The WTRU may send the uplink training bits for the online constellation learning as shown in FIG. 11. The training of the constellation may be performed at the transmitter-side (e.g., WTRU-side) by using online constellation learning feedback. As explained in the examples in this disclosure, the training can be performed through either supervised learning or reinforcement learning:

The training stage may use supervised learning techniques. The transmission and reception blocks involved in the end-to-end transmission (e.g., at the WTRU and the NW respectively) can be assumed to be differentiable or can be approximated as such. The NW and/or the WTRU may compute the gradients of end-to-end loss with respect to the trainable weights in the constellation.

The WTRU may employ a modulator with a trainable and/or learned constellation. The WTRU may modulate the uplink training bits. The WTRU may transmit the precoded symbols.

The NW may extract the received data symbols. After performing the channel estimation, equalization, demodulation, and channel decoding (e.g., optional), the NW may obtain the received bits. The NW may compute the end-to-end loss by using uplink training bits and received bits. The NW may compute and send the learned constellation performance metrics (e.g., uncoded BER, BER, BLER, throughput, AIML model loss, etc.) to the WTRU.

By using the differentiation chain rule and assuming all transmission/reception blocks are differentiable (e.g., or can be approximated), the WTRU and/or the NW may compute the gradients of end-to-end loss with respect to the trainable weights in the constellation.

By using the differentiation chain rule, the gradients of end-to-end loss with respect to the trainable weights in the constellation can be obtained. For example, the NW may compute the partial gradients and send them to the WTRU. Then, the WTRU may compute the gradients of end-to-end loss with respect to the trainable weights in the constellation through the received partial gradients.

The WTRU may train the weights through supervised learning. The WTRU may use a learning algorithm, (e.g., SGD, ADAM, RMSProp).

The training stage may use reinforcement learning techniques. In such cases, the NW may compute the learned constellation performance metrics (e.g., uncoded BER, BER, BLER, throughput, AIML model loss, etc.). The NW may send the learned constellation performance metrics to the WTRU.

The WTRU may train the constellation through reinforcement learning. In examples, a reinforcement learning agent may be located at the WTRU. Symbol points in the constellation and/or other metrics (e.g., such as SNR/SINR of the channel) may represent the state. The WTRU may calculate the reward by using the learned constellation performance metrics. For example, the reward may be a vector constructed from a metric associated with each perturbation, (e.g., mean BCE taken over all REs with the same perturbation).

The WTRU may take an action (e.g., the agent at the WTRU may take an action) to update the symbol points in the learned constellation. For example, the agent may apply a perturbation vector to the constellations representing the action of reinforcement learning agent. The perturbation vector may include the perturbations for each symbol point in the learned constellation. The decided action by the agent may move the environment from its current state to a new state.

The NW and the WTRU may perform a capability exchange related to constellation learning. The NW may initiate the WTRU capability exchange process by sending the WTRU a capability request (e.g., UECapabilityEnquiry RRC message) to the WTRU. This message may be used to request specific information regarding the WTRU's capabilities. The NW may include parameters in this message to specify one or more capabilities it is interested in. The NW may specify parameters related to WTRU's capability in supporting online constellation learning in uplink for compensating the non-linearities in PA in the WTRU capability request (e.g., UECapabilityEnquiry) message (e.g., the capability of reporting one or more learned/trained constellations, the capability for periodic and/or aperiodic reporting PA backoff level).

Upon receiving the WTRU Capability Enquiry (e.g., RRC) message, the WTRU may respond with a WTRU capability response (e.g., UECapabilityInformation RRC message) accordingly. This message may include detailed information about the WTRU's capabilities. Parameters related to the AIML functions that may be requested and/or provided during the WTRU capability exchange process between the WTRU, and the NW include, but are not limited to, the following.

During the capability exchange process, the NW may request and/or the WTRU may provide an indicator of whether reporting hardware and radio impairments (e.g., PA characteristics, PA linear power range, PA power backoff etc.) is supported or not.

During the capability exchange process, the NW may request and/or the WTRU may provide an indicator of whether online constellation learning in uplink is supported or not.

During the capability exchange process, the NW may request and/or the WTRU may provide an indicator of whether using one or more learned constellation (e.g., non-square QAM) is supported or not.

During the capability exchange process, the NW may request and/or the WTRU may provide an indicator of whether the configuration of multiple learned constellation diagrams is supported or not.

During the capability exchange process, the NW may request and/or the WTRU may provide an indicator of whether receiving online constellation learning feedback (e.g., gradients and/or learned constellation performance metrics) is supported or not.

During the capability exchange process, the NW may request and/or the WTRU may provide an indicator of whether performing online constellation learning through supervised learning is supported or not.

During the capability exchange process, the NW may request and/or the WTRU may provide an indicator of whether performing online constellation learning through reinforcement learning is supported or not.

During the capability exchange process, the NW may request and/or the WTRU may provide an indicator of whether generating the uplink training bits is supported or not. For example, the WTRU may generate the uplink training bits through a pseudo-random bit generator with the configured seeds by the NW (e.g., received in the capability request or another message). The WTRU may generate the uplink training bits through the data bits.

During the capability exchange process, the NW may request and/or the WTRU may provide an indicator of whether generating pseudo-random perturbations for creating perturbations for groups of REs is supported or not.

During the capability exchange process, the NW may request and/or the WTRU may provide an indicator of whether reporting one or more second (e.g., trained) constellation(s) is supported or not.

The NW and the WTRU may exchange configuration information for constellation learning. Through WTRU capability exchange process, the NW may learn of the WTRU's capability to support the transmitter-side training of constellation learning in uplink and/or use learned constellations. The NW may configure a WTRU that is capable of supporting such functions and/or features with one or more related parameters (e.g., via RRC signaling). Examples of parameters that may be configured by the NW, include, but are not limited to the following.

The NW may configure the WTRU with parameters for one or more initial constellation(s). The NW may configure the WTRU with an initial constellation diagram for each modulation order.

The NW may configure the WTRU with one or more initial constellation diagrams, (e.g., a single constellation diagram per sub-band, per Precoding Resource Block Group, or RB set). For example, the configuration may associate each sub-band may with a constellation diagram. For another example, the configuration may associate a first sub-band with a constellation that has 16 symbols (e.g., 4 bits per symbol), while the second sub-band is associated with a constellation with 64 symbols (e.g., 6 bits per symbol).

The configured parameters for the initial constellation diagrams may include but are not limited to one or more of the following. The parameters for the initial constellation diagrams may include a previously trained/learned constellation under a similar condition (e.g., channel conditions, hardware impairments). The parameters for the initial constellation diagrams may include a constellation that was trained/learned during online constellation learning iterations. The parameters for the initial constellation diagrams may include a square QAM constellation for the first iteration of online constellation learning.

The NW may configure the WTRU with parameters for online constellation learning training allocations. The parameters for online constellation learning training allocations may include a set of PUSCH REs on which the WTRU transmits the symbols modulated by uplink training bits.

The parameters for online constellation learning training allocations may include uplink training bits. The uplink training bits may include, but are not limited to pseudo-random data bits, or data bits. The uplink training bits may include pseudo-random data bits generated through a seed. For example, the WTRU may generate the uplink training bits through a pseudo-random bit generator with the configured seeds. The uplink training bits may include data bits. For example, the WTRU may generate the uplink training bits through the data bits.

The parameters for online constellation learning training allocations may include seed(s) to generate the uplink training bits at the NW. The parameters for online constellation learning training allocations may include seed(s) to generate pseudo-random perturbations for creating perturbations for groups of REs.

The parameters for online constellation learning training allocations may include configuration for or information about which group of REs are associated with which perturbation. The parameters for online constellation learning training allocations may include an indication of a code rate of FEC code (e.g., LDPC).

The NW may configure the WTRU with parameters for transmit power and/or PA power backoff level to be used. The NW may configure the WTRU with parameters for learning a constellation. For example, the parameters may indicate that the WTRU is to learn a constellation for each modulation order greater than 2 bits/symbol through the range defined by SNRₘᵢₙ and SNRₘₐₓ, for each modulation order. For example, the parameters may indicate that the WTRU is to learn a constellation for each modulation order and code rate (e.g., per MCS) through the configured of SNRₘᵢₙ and SNRₘₐₓ for each MCS (e.g., learning the constellations for a range of SNR in a given MCS). For example, the parameters may indicate that the WTRU is to learn a constellation foreach combination of MCS (e.g., with its associated SNR range), waveform indicator, and hardware/radio impairment class through the configured of SNRₘᵢₙ and SNRₘₐₓ for each MCS, waveform indicator, and partitioned channel BW having a common class of hardware/radio impairments.

The NW may configure the WTRU with parameters for downlink resource allocations to receive the online constellation learning feedback (e.g., gradients and/or learned constellation performance metrics). For example, the WTRU may be configured to receive the gradients of the end-to-end loss function with respect to the effective uplink channel estimate computed by the NW. For example, the WTRU is configured to receive (e.g., through DCI or MAC-CE) one or more constellation performance metric(s) for one or more configured constellation(s), which are determined by the NW. The constellation performance metrics may include BER, BLER, throughput, AIML model loss, etc. The parameters may indicate the time and or frequency resources on which the WTRU is to receive the gradients and/or performance metrics.

The NW may configure the WTRU with parameters for training related information. The parameters for training related information may include, but are not limited to, one or more of the following.: The parameters for training related information may include an indication of the learning algorithm, learning rates, regularization parameters, etc. The parameters for training related information may include an indication of the total number of training sessions. The parameters for training related information may include an indication of the online constellation learning through supervised learning or reinforcement learning.

The WTRU and/or the NW may engage in signaling related to constellation learning. The following signals may enable the WTRU (e.g., or NW) to detect the need for initiating online constellation learning in the uplink, and/or to enable the WTRU to use the learned constellation(s):

The NW may signal the WTRU with a request to report its hardware impairment information (e.g., phase noise, I/Q imbalance, carrier frequency offset, PA characteristics and/or nonlinearities). This request may be transmitted from the NW to the WTRU (e.g., through RRC signaling).

The WTRU may signal the NW with a report with the hardware impairment information. This report may be transmitted from the WTRU to the NW (e.g., through RRC signaling). The report may include an indication of PA characteristics (e.g., PA linear power range).

The NW may signal the WTRU with a training activation message. The training for the online constellation learning may be transmitted from the NW to the WTRU (e.g., through DCI or MAC-CE).

The NW may signal the WTRU with configuration information for online constellation learning training allocations. This configuration information may be transmitted from the NW to the WTRU (e.g., via RRC, MAC-CE, etc.).

The NW may signal the WTRU with learned constellation performance metrics. The learned constellation performance metrics may be transmitted from the NW to the WTRU (e.g., through DCI or MAC-CE).

The NW may signal the WTRU with gradients of the end-to-end loss with respect to the effective (e.g., precoded) uplink channel. The gradients may be transmitted from the NW to the WTRU (e.g., through RRC, DCI, MAC-CE, etc.).

The NW may signal the WTRU with online constellation learning feedback. This feedback may be transmitted from the NW to the WTRU (e.g., via RRC, DCi, MAC-CE).

The NW may signal the WTRU with configuration information for online constellation learning through supervised learning. This configuration information may be transmitted from the NW to the WTRU (e.g., via RRC, DCI, MAC-CE).

The NW may signal the WTRU with configuration information for online constellation learning through reinforcement learning. This configuration information may be transmitted from the NW to the WTRU (e.g., via RRC, DCI, MAC-CE).

The WTRU may signal the NW with an indication that training is complete. This indication may be transmitted from the WTRU to the NW (e.g., via RRC, UCI, etc.).

The NW may signal the WTRU with an indication that training is complete. This indication may be transmitted from the NW to the WTRU (e.g., via RRC, DCI, MAC-CE, etc.).

The WTRU may signal the NW with a report with one or more second (e.g., trained) constellation(s). This report may be transmitted from the WTRU to the NW (e.g., via RRC, UCI, etc.).

FIG. 15A and FIG. 15B comprise a flow chart showing an example of a WTRU procedure for transmitter-side training for online constellation learning in uplink. In the example shown in FIG. 15A and FIG. 15B, the WTRU is configured with one or more initial constellations at 1502. The one or more initial constellations may apply to one or more combinations of PA power backoff, modulation order, MCS, and/or waveform indicator.

At 1504, the WTRU may determine to start online constellation learning. At 1506, the WTRU may receive the configuration (e.g., configuration information) for online constellation learning in the uplink. At 1508, the WTRU may be configured to perform online constellation learning based on the received configuration for online constellation learning in the uplink.

For example using online constellation learning through supervised learning techniques, at 1510, the WTRU may be configured to perform online constellation learning through supervised learning. At 1514, the WTRU may receive the gradients of an end to end loss function, with respect to the effective UL channel estimate. At 1518, the WTRU may determine the gradients of the end to end loss function with respect to the trainable weights in the constellation. At 1522, the WTRU may train one or more second constellations through supervised learning.

For example using online constellation learning through reinforcement learning, at 1512, the WTRU may be configured to perform online constellation learning through reinforcement learning. At 1516, the WTRU may receive the learned constellation performance metrics. At 1520, the WTRU may compute a reward by using the learned constellation performance metrics. At 1524, the WTRU may train one or more second constellations through RL by using rewards. For example, an agent at the WTRU may take an action to update the symbol points in the constellation.

At 1526, the WTRU may report the one or more second (e.g., trained) constellations. If the training status is complete (e.g., due to loss function being below a threshold), at 1528, the WTRU may receive an indication to stop online constellation learning. At 1530, the WTRU may use the new trained constellation for uplink data transmissions. If training status is not complete, the process may be repeated (e.g., by going back to step 1508 and repeating the subsequent steps until training is completed).

Numerical Results of simulations related to online constellation learning are discussed herein. The numerical results are presented for the performance evaluation of the proposed online constellation learning. The simulations are performed by using Sionna, which is an open-source Python library for the link-level simulations based on TensorFlow.

The simulation parameters are summarized in Table 1. The WTRU is configured with 5 MHz bandwidth with numerology μ=1 (i.e., 30 kHz subcarrier spacing, 11 RBs with 132 subcarriers).

TABLE 1
Simulation parameters.

| Scenario | Downlink | |
|---|---|---|
| Number of Tx Antenna at gNB | 1 | |
| Number of Rx Antenna at WTRU | 1 | |
| Channel Model | CDL-B | |
| Delay Spread | 300 | ns |
| Channel Normalization | True (Enabled) | |
| Subcarrier Spacing | 60 | kHz |
| Carrier Frequency | 3.5 | GHz |
| Number of RBs | 11 | |
| Bandwidth | 10 | MHz |
| Number of Bits per Symbol | 6 | bits |
| Code rate | 466/1024 | |
| WTRU Velocity | 10 | km/h |

| | |
|---|---|
| SNR | [10 dB, 20 dB] |

The online constellation learning is performed through supervised learning. Specifically, a learnable constellation is trained jointly with the pretrained SSD using supervised learning as described herein. The AIML model training parameters are given in Table 2.

TABLE 2
AIML model training parameters

| | |
|---|---|
| Batch Size | 128 Slots |
| Number of Runs | 1000 for Training \| 10 for Test |
| Training Dataset Size | $128 , 000 Slots = 128 \frac{Slots}{Run} \times 1000 Runs$ |
| Optimizer | Adam |
| Learning Rate | 0.001 |
| Model Params | 128 for Constellation (i.e., Learned QAM) |
| | 17,798 for Demapper |

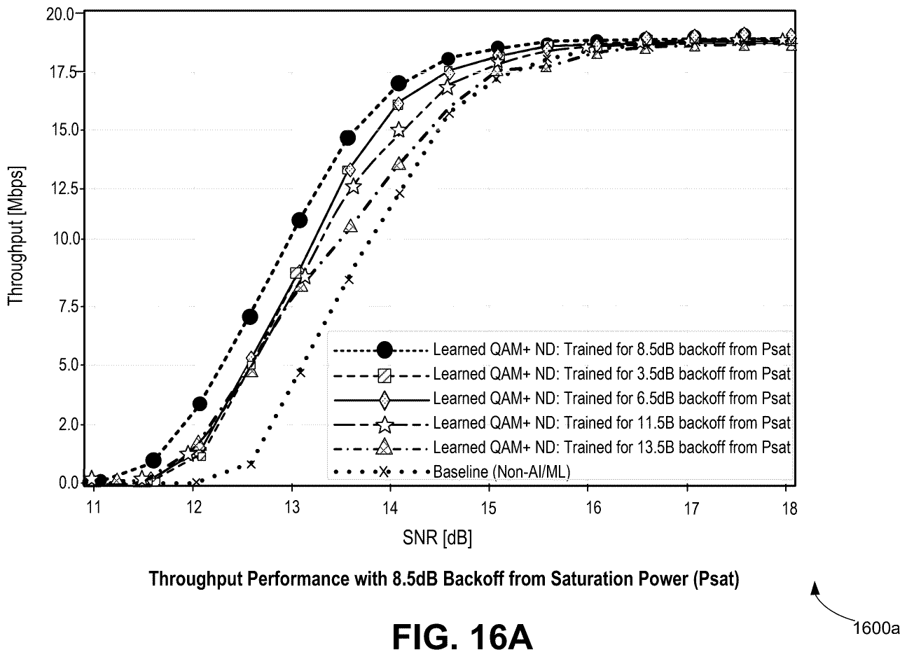

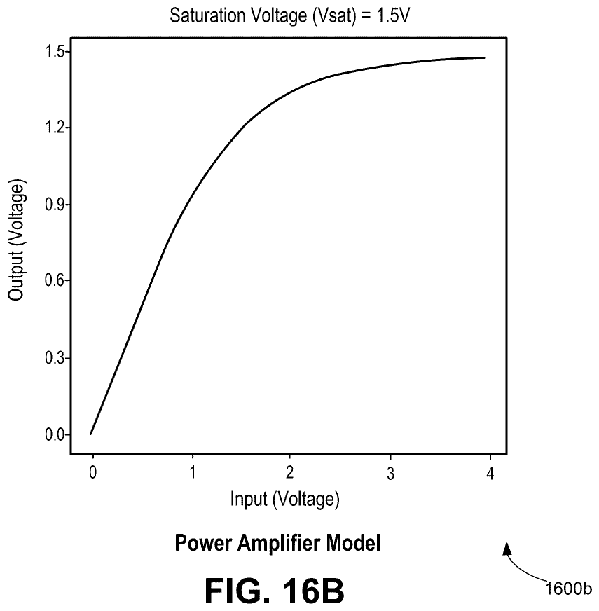

FIG. 16A, at 1600a, shows an example of relationships between signal to noise ratio (SNR) and throughput for 8.5 dB PA power backoff, for a constellation and an SSD trained for PA power backoff of 8.5 dB, 3.5 dB, 6.5 dB, 11.5 dB, and 13.5 dB, as well as for the conventional non-AI/ML constellation (QAM constellation) and SSD (i.e., baseline). FIG. 16B, at 1600b, shows the PA model used during training where the saturation voltage Vsat=1.5V.

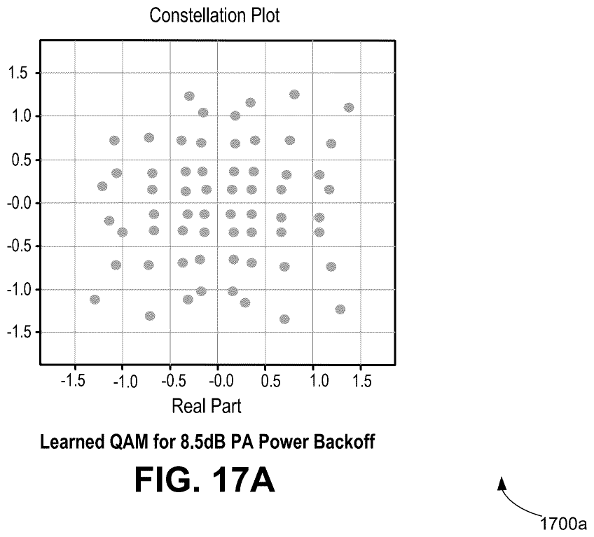

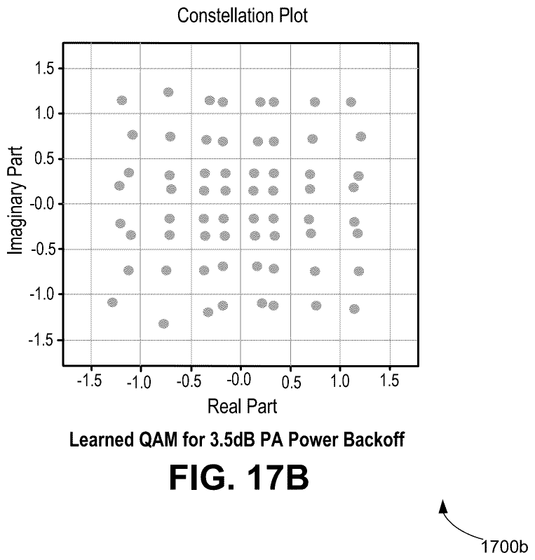

FIG. 16A shows that the learned constellations for multiple PA power backoff levels, significantly outperforms the legacy non-AI/ML constellation, which demonstrates that the constellations should be learned and optimized in order to improve the performance of the system (e.g., throughput) in the presence of PA non-linearities as proposed herein. FIG. 16A further shows that constellations learned for PA power backoff levels that are different than 8.5 dB do not perform as well as the constellation learned for PA power backoff level of 8.5 dB when the operating PA power backoff level at the WTRU is equal to 8.5 dB. This observation supports learning constellations over ranges of varying PA power backoff levels as proposed herein. FIG. 17A and FIG. 17B are constellation plots that demonstrate the real and imaginary parts of each symbol point in the learned constellations when the constellation and demapper are learned together. FIG. 17A presents the learned constellation when the PA power backoff is 8.5 dB at 1700a. FIG. 17B presents the learned constellation when the PA power backoff is 3.5 dB at 1700b. FIG. 17A and FIG. 17B show that the shape of the learned constellation changes as the PA power backoff level changes.

1. A wireless transmit/receive unit (WTRU) comprising
a processor, wherein the processor is configured to:
receive configuration information comprising one or more sets of constellation patterns;
receive information for an uplink (UL) transmission, wherein the information for the UL transmission comprises a modulation and coding scheme (MCS) or a waveform indicator;
determine a power amplifier (PA) power backoff level;
determine a constellation pattern to use for the UL transmission from the one or more sets of constellation patterns based on the MCS or waveform indicator and the PA power backoff level; and
perform the UL transmission using the constellation pattern.

2. The WTRU of claim 1, wherein the processor is further configured to:
send a report to a base station, the report comprising an indication of the PA power backoff level.

3. The WTRU of claim 2, wherein the report is associated with the UL transmission.

4. The WTRU of claim 2, wherein the report further comprises an indication of one or more resource blocks (RBs), an indication of one or more power levels corresponding to the one or more RBs, or an indication of a PA saturation level.

5. The WTRU of claim 2, wherein the processor is configured to send the report, based on a determination that the PA power backoff level is different than a prior PA power backoff level.

6. The WTRU of claim 2, wherein the processor is configured to send the report, based on a periodic timer or an aperiodic timer.

7. The WTRU of claim 1, wherein the processor is further configured to receive a request to report information related to a capability of the WTRU for using learned constellations.

8. The WTRU of claim 1, wherein the processor is further configured to send a message comprising information related to a capability of the WTRU for using learned constellations.

9. The WTRU of claim 1, wherein the configuration information comprises an indication that the WTRU is to use learned constellation patterns for one or more UL transmissions.

10. The WTRU of claim 1, wherein the processor is configured to determine the constellation pattern to use for the UL transmission, based on an indication of the constellation pattern comprised in a table, using the MCS, the waveform indicator, or the determined PA power backoff level.

11. The WTRU of claim 1, wherein the processor is configured to:
receive a request for information on supported PA models;
send information indicating a list of supported PA models; and
receive an indication to use a first PA model selected from the list of supported PA models.

12. The WTRU of claim 2, wherein the processor is configured to send the report, based on information comprised in a transmit power control (TPC) command.

13. A method to be used by a wireless transmit/receive unit (WTRU), the method comprising:
receiving configuration information comprising one or more sets of constellation patterns;
receive information for an uplink (UL) transmission, wherein the information for the UL transmission comprises a modulation and coding scheme (MCS) or a waveform indicator;
determining a power amplifier (PA) power backoff level;
determining a constellation pattern to use for the UL transmission from the one or more sets of constellation patterns based on the MCS or waveform indicator and the PA power backoff level; and
performing the UL transmission using the constellation pattern.

14. The method of claim 13, further comprising sending a report to a base station, the report comprising an indication of the PA power backoff level.

15. The method of claim 14, further comprising sending the report, based on a determination that the PA power backoff level is different than a prior PA power backoff level.

16. The method of claim 13, further comprising receiving a request to report information related to the WTRU's capabilities for using learned constellations.

17. The method of claim 13, further comprising sending a message comprising information related to the WTRU's capabilities for using learned constellations.

18. The method of claim 13, further comprising determining the constellation pattern to use for the UL transmission, based on an indication of the constellation pattern comprised in a table, using the MCS, the waveform indicator, or the determined PA power backoff level.

19. The method of claim 13, further comprising:
receiving a request for information on supported PA models;
sending information indicating a list of supported PA models; and
receiving an indication to use a first PA model selected from the list of supported PA models.

20. The method of claim 14, further comprising sending the report, based on information comprised in a transmit power control (TPC) command.
